(19) United States
(12) Patent Application Publication
(10) Pub. No.: US 2025/0140619 A1
(43) Pub. Date: May 1, 2025

(54) SEMICONDUCTOR PACKAGE WITH A FAN-OUT LEVEL PACKAGE

(71) Applicant: SAMSUNG ELECTRONICS CO., LTD., Suwon-si (KR)

(72) Inventors: Bongsoo KIM, Suwon-si (KR); Chobi KIM, Suwon-si (KR); Pyunghwa HAN, Suwon-si (KR)

(73) Assignee: SAMSUNG ELECTRONICS CO., LTD., Suwon-si (KR)

(21) Appl. No.: 18/927,331

(22) Filed: Oct. 25, 2024

(30) Foreign Application Priority Data
Oct. 27, 2023 (KR) 10-2023-0145934

(51) Int. Cl. H01L 23/14; H01L 23/00; H01L 23/31; H01L 23/498

(52) U.S. Cl. CPC H01L 23/145; H01L 23/3107; H01L 23/49833; H01L 24/20; H01L 2224/214; H01L 2224/221

(57) ABSTRACT

A semiconductor package includes: a first interconnection structure; an expanded layer arranged on the first interconnection structure, the expanded layer comprising a plurality of expanded base layers; a semiconductor chip arranged in a mounting space and electrically connected to the first interconnection structure; a filling insulating layer configured to fill the mounting space; and a second interconnection structure arranged on the expanded layer and the filling insulating layer, the second interconnection structure electrically connected to the first interconnection structure through a plurality of via structures, in which a surface of a lowermost expanded base layer among the plurality of expanded base layers is positioned at a higher vertical level than a surface of the filling insulating layer, and a sink space is confined by the expanded layer and the filling insulating layer under a surface of the lowermost expanded base layer among the plurality of expanded base layers.

### CROSS-REFERENCE TO RELATED APPLICATION

This application is based on and claims priority under 35 U.S.C. § 119 to Korean Patent Application No. 10-2023-0145934, filed on Oct. 27, 2023, in the Korean Intellectual Property Office, the disclosure of which is incorporated by reference herein in its entirety.

### BACKGROUND

### 1. Field

The embodiments of the present disclosure relates to a semiconductor package, and more particularly, to a fan-out panel level package (FOPLP) and a package-on-package (POP) including the same.

### 2. Description of Related Art

With the rapid development of the electronics industry and the increase in user demand, electronic devices are becoming miniaturized, multifunctional, and significantly more dense. As a result, highly integrated semiconductor chips are required.

Therefore, semiconductor packages including connection terminals with connection reliability have been designed for highly integrated semiconductor chips with an increased number of input/output (I/O) connection terminals. For example, a fan-out semiconductor package, such as an fan-out panel level package (FOPLP), has been developed to prevent interference between the connection terminals by increasing the spacing therebetween. When a panel used for a fan-out panel level package (FOPLP) is used as an embedded trace substrate (ETS), circuit patterning may be performed on a flat surface, and thus, a fine circuit pattern may be realized.

However, in the related art, a cavity (e.g., a mounting space) is fabricated after circuit patterning performed on opposite surfaces (e.g., upper and lower surfaces) of a panel, and thus, during cavity formation, there are problems including delamination between a circuit pattern and a panel base layer, an increase in roughness on the circuit pattern, and the generation of cracks.

### SUMMARY

The embodiments of the present disclosure provides a semiconductor package with improved electrical reliability.

According to one or more embodiments, a semiconductor package comprising: a first interconnection structure; an expanded layer arranged on the first interconnection structure, the expanded layer comprising a plurality of expanded base layers, a cover resin layer covering a surface of at least one expanded base layer from an uppermost portion among the plurality of expanded base layers, a plurality of via structures penetrating the plurality of expanded base layers and the cover resin layer, and a mounting space penetrating the plurality of expanded base layers; a semiconductor chip arranged in the mounting space and electrically connected to the first interconnection structure; a filling insulating layer configured to fill the mounting space; and a second interconnection structure arranged on the expanded layer and the filling insulating layer, the second interconnection structure electrically connected to the first interconnection structure through the plurality of via structures, wherein a surface of a lowermost expanded base layer among the plurality of expanded base layers is positioned at a higher vertical level than a surface of the filling insulating layer, and a sink space is confined by the expanded layer and the filling insulating layer under the surface of the lowermost expanded base layer among the plurality of expanded base layers.

According to one or more embodiments, a semiconductor package comprising: a first interconnection structure comprising a first redistribution insulating layer, a plurality of first redistribution line patterns arranged on at least one of a first surface and a second surface of the first redistribution insulating layer, and a plurality of first redistribution vias penetrating the first redistribution insulating layer and respectively connected to one or more of the plurality of first redistribution line patterns; an expanded layer arranged on the first interconnection structure, the expanded layer comprising a plurality of expanded base layers, a cover resin layer covering a surface of at least one of the plurality of expanded base layers from an uppermost portion among the plurality of expanded base layers, a plurality of via structures penetrating the cover resin layer and the plurality of expanded base layers and respectively connected to one or more of the plurality of first redistribution vias, and a mounting space penetrating the plurality of expanded base layers; a semiconductor chip arranged in the mounting space and comprising a plurality of chip pads connected to a respective first redistribution via from the plurality of first redistribution vias; a filling insulating layer configured to fill the mounting space and cover a surface of the semiconductor chip and a surface of the expanded layer; and a second interconnection structure arranged on the filling insulating layer, the second interconnection structure comprising a second redistribution insulating layer, a plurality of second redistribution line patterns arranged on at least one of a first surface and a second surface of the second redistribution insulating layer, and a plurality of second redistribution vias penetrating the second redistribution insulating layer and respectively connected to one or more of the plurality of second redistribution line patterns, the second interconnection structure being electrically connected to the first interconnection structure through the plurality of via structures, wherein a surface of a lowermost expanded base layer among the plurality of expanded base layers is positioned at a higher vertical level than a surface of the filling insulating layer, and a sink space is confined by the expanded layer and the filling insulating layer under the surface of the lowermost expanded base layer among the plurality of expanded base layers, and the sink space is filled with a portion of the first redistribution insulating layer and portions of an uppermost first redistribution via among the plurality of first redistribution vias.

According to one or more embodiments, a semiconductor package comprising: a first interconnection structure comprising a first redistribution insulating layer, a plurality of first redistribution line patterns arranged on at least one of a first surface and a second surface of the first redistribution insulating layer, and a plurality of first redistribution vias penetrating the first redistribution insulating layer and respectively connected to one or more of the plurality of first redistribution line patterns; an expanded layer arranged on the first interconnection structure, the expanded layer comprising a plurality of expanded base layers, a cover resin layer covering a surface of at least one expanded base layer from an uppermost portion among the plurality of expanded base layers, a plurality of via structures penetrating the cover resin layer and the plurality of expanded base layers and respectively connected to one or more of the plurality of first redistribution vias, and a mounting space penetrating the plurality of expanded base layers, wherein the plurality of via structures comprise a plurality of via connection pattern portions and a plurality of extended via portions connecting two via connection pattern portions that are positioned at different vertical levels among the plurality of via connection pattern portions; a semiconductor chip arranged in the mounting space and comprising a plurality of chip pads connected to a respective first redistribution via from the plurality of first redistribution vias and buried in the first redistribution insulating layer; a filling insulating layer configured to fill the mounting space and cover a surface of the semiconductor chip and a surface of the expanded layer; and a second interconnection structure arranged on the filling insulating layer, the second interconnection structure comprising a second redistribution insulating layer, a plurality of second redistribution line patterns arranged on at least one of a first surface and a second surface of the second redistribution insulating layer, and a plurality of second redistribution vias penetrating the second redistribution insulating layer and respectively connected to one or more of the plurality of second redistribution line patterns, the second interconnection structure being electrically connected to the first interconnection structure through the plurality of via structures, wherein a surface of a lowermost expanded base layer among the plurality of expanded base layers is positioned at a higher vertical level than the surface of the filling insulating layer, and wherein a portion of the first surface of the first redistribution insulating layer contacting the expanded layer is positioned at a higher vertical level than a portion of the first surface of the first redistribution insulating layer contacting the surface of the filling insulating layer.

### BRIEF DESCRIPTION OF DRAWINGS

Embodiments will be more clearly understood from the following detailed description taken in conjunction with the accompanying drawings in which:

FIGS. 1A and 1B are cross-sectional views of a semiconductor package that is a fan-out panel level package (FOPLP), according to embodiments;

FIGS. 2A to 2T are cross-sectional views showing a method of manufacturing a semiconductor package that is an FOPLP, according to embodiments;

FIGS. 3A and 3B are cross-sectional views of a semiconductor package that is an FOPLP, according to embodiments;

FIGS. 4A and 4B are cross-sectional views of a semiconductor package that is an FOPLP, according to embodiments; and

FIG. 5 is a cross-sectional view of a semiconductor package that is a package-on-package, according to embodiments.

### DETAILED DESCRIPTION

Hereinafter, example embodiments will be described with reference to the accompanying drawings. Hereinafter, terms, such as ‘top,’ ‘upper portion,’ ‘upper surface,’ ‘bottom,’ ‘lower portion,’ ‘lower surface,’ and ‘side surface’ may be understood as illustrated in the drawings, except for cases indicated by reference numerals.

It will be understood that, although the terms first, second, third, fourth, etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of the disclosure.

It will be understood that when an element or layer is referred to as being “over,” “above,” “on,” “below,” “under,” “beneath,” “connected to” or “coupled to” another element or layer, it can be directly over, above, on, below, under, beneath, connected or coupled to the other element or layer or intervening elements or layers may be present. In contrast, when an element is referred to as being “directly over,” “directly above,” “directly on,” “directly below,” “directly under,” “directly beneath,” “directly connected to” or “directly coupled to” another element or layer, there are no intervening elements or layers present.

A layer may be described as having an upper surface and a lower surface. As understood by one of ordinary skill in the art, the surfaces of a layer may also be described as first and second surfaces, where a first surface may be one of the upper surface and the lower surface of the layer, and the second surface may be the other of the upper surface and the lower surface of the layer.

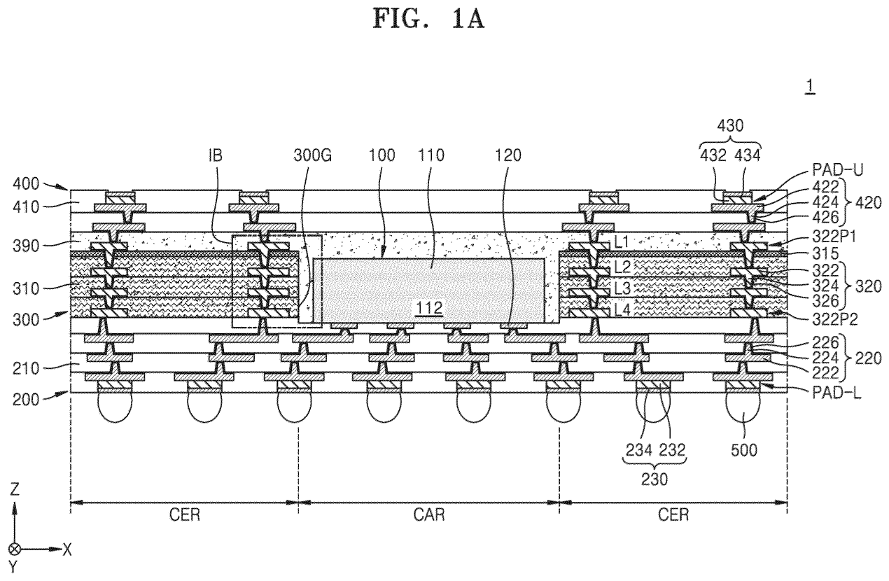

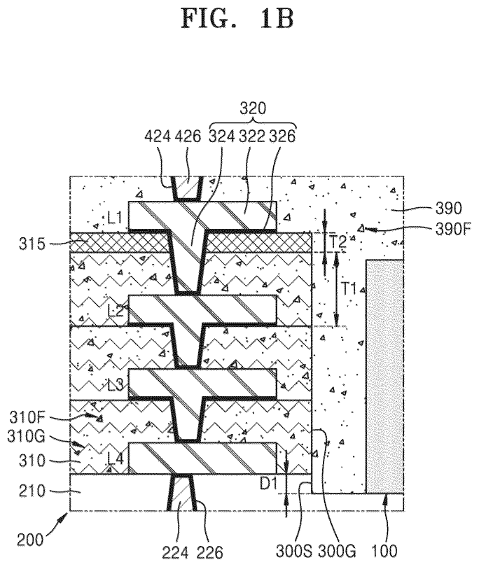

FIGS. 1A and 1B are cross-sectional views of a semiconductor package that is a fan-out panel level package (FOPLP), according to embodiments. In detail, FIG. 1B is a cross-sectional view showing an enlarged region IB of FIG. 1A.

Referring to FIGS. 1A and 1B together, a semiconductor package 1 may include a first interconnection structure 200, a second interconnection structure 400 on the first interconnection structure 200, at least one semiconductor chip 100 arranged between the first interconnection structure 200 and the second interconnection structure 400, and an expanded layer 300 arranged between the first interconnection structure 200 and the second interconnection structure 400 and encircling the surroundings of the at least one semiconductor chip 100. The expanded layer 300 may be configured to electrically connect the first interconnection structure 200 to the second interconnection structure 400. In some embodiments, the semiconductor package 1 may be an FOPLP. The semiconductor package 1 may include a chip accommodation region CAR, in which at least one semiconductor chip 100 is arranged, and a chip peripheral region CER around the chip accommodation region CAR. The chip accommodation region CAR may have a planar rectangular shape, and the chip peripheral region CER may surround the chip accommodation region CAR. The chip peripheral region CER may be planar.

In some embodiments, at least one of the first interconnection structure 200 and the second interconnection structure 400 may be formed through a redistribution process. The first interconnection structure 200 and the second interconnection structure 400 may be referred to as a first redistribution structure and a second redistribution structure, respectively, or as a lower redistribution structure and an upper redistribution structure, respectively. In some embodiments, the semiconductor package 1 may be formed in a chip-first manner in which the expanded layer 300 and at least one semiconductor chip 100 are prepared first, and then the first interconnection structure 200 and the second interconnection structure 400 are formed. In some embodiments, at least one of the first interconnection structure 200 and the second interconnection structure 400 may be a printed circuit board (PCB).

The first interconnection structure 200 may include a first redistribution insulating layer 210 and a plurality of first redistribution patterns 220. The first redistribution insulating layer 210 may surround the first redistribution patterns 220. In some embodiments, the first interconnection structure 200 may include a plurality of first redistribution insulating layers 210 that are stacked. In one or more examples, the first redistribution insulating layer 210 may include a resin including an organic material. For example, the first redistribution insulating layer 210 may be formed from a photo imageable dielectric (PID) or photosensitive polyimide (PSPI).

The first redistribution patterns 220 may each include metals, for example, copper (Cu), aluminum (Al), tungsten (W), titanium (Ti), tantalum (Ta), indium (In), molybdenum (Mo), manganese (Mn), cobalt (Co), tin (Sn), nickel (Ni), magnesium (Mg), rhenium (Re), beryllium (Be), gallium (Ga), or ruthenium (Ru), or alloys thereof, but one or more embodiments are not limited thereto. The first redistribution patterns 220 may include a plurality of first redistribution line patterns 222, a plurality of first redistribution vias 224, and a plurality of first redistribution seed layers 226. The first redistribution vias 224 may penetrate at least one first redistribution insulating layer 210 such that the first redistribution vias 224 contact and connect to one or more first redistribution line patterns 222. In some embodiments, the first redistribution vias 224 may each have a tapered shape extending upwards from the lower portion of the first redistribution via 224 and decreasing in horizontal width. For example, the first redistribution vias 224 may each have the horizontal width decreasing closer to the at least one semiconductor chip 100.

In some embodiments, at least some of the first redistribution line patterns 222 may be formed together with some of the first redistribution vias 224 and be integral. For example, the first redistribution line pattern 222 and the first redistribution via 224 contacting the upper surface of the first redistribution line pattern 222 (e.g., the first redistribution via 224 extending upwards from the upper surface of the first redistribution line pattern 222), may be formed together as a single body. For example, each first redistribution via 224 may have a horizontal width decreasing away from the first redistribution line pattern 222 that is formed integrally with the first redistribution via 224.

The first redistribution seed layer 226 may extend over the first redistribution line pattern 222 and the first redistribution via 224 that are formed integrally with each other. For example, the first redistribution seed layer 226 may cover the upper surface of the first redistribution line pattern 222, and the side and upper surfaces of the first redistribution via 224 among the surfaces of the first redistribution line pattern 222 and the first redistribution via 224 that are formed integrally with each other. In one or more examples, the first redistribution seed layer 226 does not cover the side and lower surfaces of the first redistribution line pattern 222. In some embodiments, the first redistribution seed layer 226 may be formed to be a portion of the first redistribution line pattern 222 or a portion of the first redistribution via 224. For example, when the first redistribution line pattern 222 or the first redistribution via 224 contacting the first redistribution seed layer 226 is formed after the formation of the first redistribution seed layer 226, the first redistribution line pattern 222 or the first redistribution via 224 contacting the first redistribution seed layer 226 may be formed integrally with the first redistribution seed layer 226 with an undifferentiated boundary. For example, a portion of the first redistribution seed layer 226 contacting the first redistribution line pattern 222 may be a portion of the first redistribution line pattern 222, and a portion of the first redistribution seed layer 226 contacting the first redistribution via 224 may be a portion of the first redistribution via 224.

In one or more examples, the first redistribution line pattern 222 may include the same material as the first redistribution via 224. However, as understood by one of ordinary skill in the art, the first redistribution line pattern 222 and the first redistribution via 224 may be formed of different materials. In some embodiments, the first redistribution seed layer 226 may include the same material as each of the first redistribution line pattern 222 and the first redistribution via 224. In some embodiments, the first redistribution line pattern 222, the first redistribution via 224, and the first redistribution seed layer 226 may include Cu. For example, the first redistribution line pattern 222, the first redistribution via 224, and the first redistribution seed layer 226 may include Cu or Cu alloys. In some embodiments, the first redistribution seed layer 226 may include a different material from each of the first redistribution line pattern 222 and the first redistribution via 224. In some embodiments, the first redistribution seed layer 226 may include Ti. For example, the first redistribution seed layer 226 may include Ti or titanium nitride (TiN).

The first interconnection structure 200 may include a plurality of lower surface connection pads PAD-L arranged on a lower surface of the first interconnection structure 200. In some embodiments, each lower surface connection pad PAD-L may include a lower surface connection pad layer 230 covering a lower surface of a portion of the first redistribution line pattern 222. The lower surface connection pad layer 230 may include a first lower surface metal layer 232 and a second lower surface metal layer 234, which are sequentially stacked on the lower surface of the portion of the first redistribution line pattern 222. In some embodiments, the first lower surface metal layer 232 may include Ni, and the second lower surface metal layer 234 may include gold (Au), but one or more embodiments are not limited thereto. A plurality of external connection terminals 500 may be attached to the lower surface connection pads PAD-L, respectively. The external connection terminals 500 may externally connect the semiconductor package 1.

At least one semiconductor chip 100 may be attached to the first interconnection structure 200. The semiconductor chip 100 may include a semiconductor substrate 110 including an active surface and an inactive surface that are opposite to each other, a semiconductor device 112 formed on the active surface of the semiconductor substrate 110, and a plurality of chip pads 120 arranged on the active surface of the semiconductor substrate 110. The semiconductor chip 100 may include a first surface and a second surface that are opposite to each other. The chip pads 120 may be arranged on the first surface of the semiconductor chip 100. The second surface of the semiconductor chip 100 may be the inactive surface of the semiconductor substrate 110. As understood by one of ordinary skill in the art, the active surface of the semiconductor substrate 110 is very close to the first surface of the semiconductor chip 100. However, there may be a separation between the active surface of the semiconductor substrate 110 and the first surface of the semiconductor chip 100. In some embodiments, the chip pads 120 may protrude from the first surface of the semiconductor chip 100 and be buried in the first interconnection structure 200. For example, at least a portion of each chip pad 120 may be buried in the first redistribution insulating layer 210 that is the uppermost among the first redistribution insulating layers 210. The chip pads 120 may contact and be connected to some of the first redistribution patterns 220. For example, the chip pads 120 may contact and be connected to one or more of the uppermost first redistribution vias 240.

The semiconductor substrate 110 may include a semiconductor material, such as silicon (Si) or germanium (Ge). In one or more examples, the semiconductor substrate 110 may include compound semiconductor materials, such as silicon carbide (SiC), gallium arsenide (GaAs), indium arsenide (InAs), and indium phosphide (InP). The semiconductor substrate 110 may include conductive regions, for example, wells doped with impurities. The semiconductor substrate 110 may have various device isolation structures, such as a shallow trench isolation (STI) structure.

In one or more examples, on the active surface of the semiconductor substrate 110, the semiconductor devices 112 including various types of individual devices are formed. The individual devices may include various microelectronic devices, for example, a metal-oxide-semiconductor field effect transistor (MOSFET) such as a complementary metal-insulator-semiconductor (CMOS) transistor, system large scale integration (LSI), active elements, passive elements, or any other suitable microelectronic devices known to one of ordinary skill in the art. The individual devices may be electrically connected to the conductive regions of the semiconductor substrate 110. The semiconductor device 112 may further include a conductive line or a conductive plug configured to electrically connect at least two of the individual devices or the individual devices to the conductive regions of the semiconductor substrate 110. In one or more examples, the individual devices may be electrically separated from other neighboring individual devices by a respective insulating layer.

In some embodiments, the semiconductor chip 100 may include a logic device. For example, the semiconductor chip 100 may be a central processing unit (CPU) chip, a graphics processing unit (GPU) chip, or an application processor (AP) chip. In some embodiments, the semiconductor chip 100 may be a memory semiconductor chip including a memory device. For example, the memory device may be a non-volatile memory device, such as flash memory, phase-change random access memory (PRAM), magneto-resistive random access memory (MRAM), ferroelectric random access memory (FeRAM), or resistive random access memory (RRAM). The flash memory may be, for example, NAND flash memory or V-NAND flash memory. In some embodiments, the memory device may be a volatile memory device, such as dynamic random access memory (DRAM) or static random access memory (SRAM). In some embodiments, when the semiconductor package 1 includes a plurality of semiconductor chips 100, at least one of the semiconductor chips 100 may be a CPU chip, a GPU chip, or an AP chip, and at least another one of the semiconductor chips 100 may be a memory semiconductor chip including a memory device.

In some embodiments, the semiconductor chip 100 may have a face-down arrangement in which the first surface faces the first interconnection structure 200 and may be attached to the upper surface of the first interconnection structure 200. For example, the semiconductor chip 100 may be arranged on the first interconnection structure 200 to make the chip pads 120 face the first interconnection structure 200. In this case, the first surface of the semiconductor chip 100 may be referred to as the lower surface of the semiconductor chip 100, and the second surface of the semiconductor chip 100 may be referred to as the upper surface of the semiconductor chip 100.

The expanded layer 300 may include an expanded base layer 310 and a plurality of via structures 320. The expanded layer 300 may include a mounting space 300G where at least one semiconductor chip 100 is arranged. The via structures 320 may penetrate from the upper surface of the expanded base layer 310 to the lower surface thereof. The expanded layer 300 may be an embedded trace substrate (ETS), a PCB, a ceramic substrate, a wafer for manufacturing a package, or an interposer. In some embodiments, the expanded layer 300 may include at least two expanded base layer 310 that are stacked.

In one or more examples, the mounting space 300G may be formed as an opening or a cavity in the expanded layer 300. The mounting space 300G may be formed in some regions of the expanded layer 300, for example, a central region of the expanded layer 300 in the plan view. The mounting space 300G may be formed to penetrate from the upper surface of the expanded layer 300 to the lower surface thereof.

In one or more examples, the mounting space 300G may be positioned in the chip accommodation region CAR of the expanded layer 300, and the expanded base layer 310 and the via structures 320 may be positioned in the chip peripheral region CER. In the plan view, for example, the chip accommodation region CAR may be a region including the mounting space 300G, and the chip peripheral region CER may be a region including the expanded base layer 310 and the via structures 320.

The expanded base layer 310 may include a resin including an organic material. In some embodiments, the expanded base layer 310 may be formed from PID or PSPI. In some embodiments, the expanded base layer 310 may include at least one material selected from among phenol resin, epoxy resin, and polyimide. For example, the expanded base layer 310 may include at least one material selected from among frame retardant 4 (FR-4), tetrafunctional epoxy, polyphenylene ether, epoxy/polyphenylene oxide, bismaleimide triazine (BT), thermount, cyanate ester, polyimide, and a liquid crystal polymer. In some embodiments, the expanded base layer 310 may include prepreg. The expanded base layer 310 may have a first thickness T1. For example, the first thickness T1 may be in a range of about 20 μm to about 50 μm.

For example, the expanded base layer 310 may be in the form of a sheet made by impregnating a reinforced material 310G with a bonding material. The reinforced material 310G may include glass cloth, carbon cloth, non-woven glass fabric, or aramid cloth. The bonding material may include a thermosetting resin, such as epoxy resin, polyester resin, or polyimide, or a thermoplastic resin. In some embodiments, the expanded base layer 310 may contain a first filler 310F. For example, the first filler 310F may include a ceramic-based material having non-conductive insulation characteristics. In some embodiments, the first filler 310F may include at least one of aluminum nitride (AlN), boron nitride (BN), aluminum oxide (Al₂O₃), SiC, and magnesium oxide (MgO). For example, the first filler 310F may be a silica filler or an alumina filler. In one or more examples, the average diameter of the first filler 310F may be several μm to several tens of μm.

In one or more examples, each via structure 320 may include a via connection pattern portion 322, an extended via portion 324, and a via seed layer 326. The via connection pattern portion 322 may be arranged on the upper surface or the lower surface of the expanded base layer 310. For example, when the expanded layer 300 includes a plurality of expanded base layers 310 that are stacked, the via connection pattern portions 322 may be arranged on at least some of the upper surface of the uppermost expanded base layer 310, the lower surface of the lowermost expanded base layer 310, and between two adjacent expanded base layers 310 among the expanded base layers 310. The extended via portion 324 may penetrate at least one expanded base layer 310 and extend in a vertical direction (e.g., a Z direction). The extended via portion 324 may connect between two via connection pattern portions 322 located at different vertical levels.

In some embodiments, at least one or more of the via connection pattern portions 322 may be formed together with one or more of the extended via portions 324, thereby resulting in an integral structure. For example, the via connection pattern portion 322 and the extended via portion 324 contacting the lower surface of the via connection pattern portion 322 (e.g., the extended via portion 324 extending downwards from the lower surface of the via connection pattern portion 322), may be formed together as a single body. In some embodiments, the extended via portions 324 may each have a tapered shape extending with a width horizontally narrowing in a downward direction (e.g., a direction towards the first interconnection structure 200 from the second interconnection structure 400). For example, each extended via portion 324 may have a horizontal width decreasing away from the via connection pattern portion 322 that is integrally formed with the extended via portion 324.

The via seed layer 326 may extend under the via connection pattern portion 322 and the extended via portion 324 that are formed integrally with each other. For example, the via seed layer 326 may cover the lower surface of the via connection pattern portion 322 and the side and lower surfaces of the extended via portion 324 among the surfaces of the via connection pattern portion 322 and the extended via portion 324 that are formed integrally with each other. The via seed layer 326 may not cover the side and upper surfaces of the via connection pattern portion 322. In some embodiments, the via seed layer 326 may be formed to be a portion of the via connection pattern portion 322 or the extended via portion 324. For example, when the via connection pattern portion 322 or the extended via portion 324 contacting the via seed layer 326 is formed after the formation of the via seed layer 326, the via connection pattern portion 322 or the extended via portion 324 contacting the via seed layer 326 may be formed integrally with the via seed layer 326 with an undifferentiated boundary. For example, a portion of the via seed layer 326 that contacts the via connection pattern portion 322 may be a portion of the via connection pattern portion 322, and a portion of the via seed layer 326 that contacts the extended via portion 324 may be a portion of the extended via portion 324. In some embodiments, the via seed layer 326 may not cover the lower surface of the via connection pattern portion 322 that is the lowermost among the via connection pattern portions 322.

The via structures 320 may each include, for example, Cu or alloys containing the same. The via connection pattern portion 322 may include the same material as the extended via portion 324. In some embodiments, the via connection pattern portion 322 and the extended via portion 324 may include electrolytically deposited (ED) copper, rolled-annealed (RA) copper foil, stainless steel foil, aluminum foil, ultra-thin copper foil, sputtered copper, copper alloys, or any other suitable material known to one of ordinary skill in the art. In some embodiments, the via seed layer 326 may include the same material as each of the via connection pattern portion 322 and the extended via portion 324. In some embodiments, the via connection pattern portion 322, the extended via portion 324, and the via seed layer 326 may each include Cu or Cu alloys. In some embodiments, the via seed layer 326 may include a different material from each of the via connection pattern portion 322 and the extended via portion 324. In some embodiments, the via seed layer 326 may have a structure in which Cu is stacked on Ti, titanium tungsten (TiW), TiN, Ta, tantalum nitride (TaN), or chromium (Cr).

Each of the uppermost via connection pattern portions 322 among the via connection pattern portions 322 of the via structures 320 may be referred to as an upper surface expanded connection pad 322P1, and each of the lowermost via connection pattern portions 322 may be referred to as a lower surface expanded connection pad 322P2. The lower surface expanded connection pads 322P2 may be buried in the lowermost expanded base layer 310. The lower surfaces of the lower surface expanded connection pads 322P2 and the lower surface of the lowermost expanded base layer 310 may be located at the same vertical level and may be coplanar.

The expanded layer 300 may further include a cover resin layer 315. In some embodiments, the cover resin layer 315 may cover the upper surface of the uppermost expanded base layer 310, except for portions of the upper surface of the uppermost expanded base layer 310 that are penetrated by the connection pads 322P1. The cover resin layer 315 may include a resin including an organic material. The cover resin layer 315 may have a second thickness T2. The second thickness T2 may be less than the first thickness T1. For example, the second thickness T2 may be in a range of about 2 μm to about 7 μm. The cover resin layer 315 may not include the first filler 310F and the reinforced material 310G included in the expanded base layer 310. The uppermost via connection pattern portions 322 among the via connection pattern portions 322 may be arranged on the cover resin layer 315, and the uppermost extended via portions 324 among the extended via portions 324 may penetrate the cover resin layer 315 and the uppermost expanded base layer 310. The upper surface expanded connection pads 322P1 may not be buried in the uppermost expanded base layer 310 and the cover resin layer 315 and may protrude upwards from the upper surface of the cover resin layer 315.

The semiconductor package 1 may further include a filling insulating layer 390 that fills the mounting space 300G. The filling insulating layer 390 may fill a gap between the expanded base layer 310 and at least one semiconductor chip 100 arranged in the mounting space 300G. The filling insulating layer 390 may be formed to fill the mounting space 300G and cover the upper surface of the expanded layer 300 and the upper surface (e.g., the second surface, of the semiconductor chip 100). The filling insulating layer 390 may include a resin including an organic material-based resin. For example, the filling insulating layer 390 may include a thermosetting resin, such as epoxy resin, polyester resin, or polyimide, or a thermoplastic resin. In some embodiments, the filling insulating layer 390 may include a second filler 390F. The second filler 390F may be substantially the same as the first filler 310F. The filling insulating layer 390 may not include a reinforced material, such as glass cloth, carbon cloth, non-woven glass fabric, or aramid cloth. For example, the filling insulating layer 390 may be formed from an Ajinomoto Build-up Film (ABF), FR-4, BT, or any other suitable material known to one of ordinary skill in the art. In one or more examples, the filling insulating layer 390 may be formed from a molding material, such as an epoxy mold compound (EMC), or a photosensitive material, such as a photo imageable encapsulant (PIE). In some embodiments, a portion of the filling insulating layer 390 may include an insulative material, such as a silicon oxide layer, a silicon nitride layer, or a silicon oxynitride layer.

In some embodiments, the first surface of at least one semiconductor chip 100 and the lower surface of the filling insulating layer 390 may be positioned at the same vertical level and thus be coplanar, but one or more embodiments are not limited thereto. For example, the lowermost portion of the filling insulating layer 390 may be positioned at a lower vertical level than the first surface of the at least one semiconductor chip 100 and the lower surface of the expanded base layer 310, but at a higher vertical level than the lower surfaces of the chip pads 120.

In one or more examples, the lower surface of the lowermost expanded base layer 310 may be positioned at a higher vertical level than the first surface of the at least one semiconductor chip 100 and the lower surface of the filling insulating layer 390, and the sink space 300S may be confined by the expanded layer 300 and the filling insulating layer 390. For example, the lower surface of the lowermost expanded base layer 310 and the lower surface of the lower expanded connection pad 322P2 may be positioned with a sink depth D1 of about 2 μm about 5 μm below the lower surface of the filling insulating layer 390. For example, the lower surface of the lowermost expanded base layer 310 and the lower surface of the lower surface expanded connection pad 322P2 may be positioned at a vertical level higher than that of the lower surface of the filling insulating layer 390 by about 2 μm about 5 μm. The sink space 300S may be filled with a portion of the first interconnection structure 200, for example, an upper portion of each of the uppermost first redistribution insulating layer 210 and the uppermost first redistribution via 224. The uppermost surface of the uppermost first redistribution insulating layer 210 and the uppermost surface of each uppermost first redistribution via 224 may be positioned at a higher vertical level than the lower surface of the filling insulating layer 390. The uppermost surface of the uppermost first redistribution insulating layer 210 and the uppermost surface of each uppermost first redistribution via 224 may be at the same vertical level as the lower surface of the lowermost expanded base layer 310 and the lower surface of the lower surface expanded connection pad 322P2. A portion of the upper surface of the uppermost first redistribution insulating layer 210 contacting the lower surface of the expanded layer 300 may be positioned at a higher vertical level than a portion of the upper surface of the uppermost first redistribution insulating layer 210 that contacts the lower surface of the semiconductor chip 100 and the lower surface of the filling insulating layer 390 by as much as the sink depth D1.

In one or more examples, the via connection pattern portions 322 included in the expanded layer 300 may constitute a plurality of wiring layers. The wiring layer may refer to a portion in which an electrical path may be formed, in which the electrical path extends along a horizontal plane formed by a first horizontal direction (an X direction) and a second horizontal direction (a Y direction). For example, the expanded layer 300 may include one additional wiring layer compared to the number of expanded base layers 310 included in the expanded layer 300. For example, the wiring layers may include a first wiring layer L1, a second wiring layer L2, a third wiring layer L3, and a fourth wiring layer L4 which are positioned at different vertical levels. The first wiring layer L1, the second wiring layer L2, the third wiring layer L3, and the fourth wiring layer LA may be sequentially arranged from the upper portion of the expanded layer 300 to the lower portion thereof. When the expanded layer 300 includes three expanded base layers 310, there may be four wiring layers including the first wiring layer L1, the second wiring layer L2, the third wiring layer L3, and the fourth wiring layer LA. The uppermost via connection pattern portions 322 among the via connection pattern portions 322 may form the first wiring layer L1, and the lowermost via connection pattern portions among the via connection pattern portions 322 may form the fourth wiring layer L4. Each of the via connection pattern portions 322 forming the first wiring layer L1 may be the upper surface expanded connection pad 322P1, and each of the via connection pattern portions 322 forming the fourth wiring layer L4 may be the lower surface expanded connection pad 322P2.

In one or more examples, one or more of the via connection pattern portions 322 may be buried in the expanded base layer 310. In some embodiments, the via connection pattern portions 322 forming the first wiring layer L1 may not be buried in the expanded base layer 310, while the via connection pattern portions 322 forming the second wiring layer L2, the third wiring layer L3, and the fourth wiring layer LA may be buried in the expanded base layer 310. In some embodiments, lower surfaces of the via connection pattern portions 322 forming the fourth wiring layer LA may be at a higher vertical level than the first surface of at least one semiconductor chip 100 and the lower surface of the filling insulating layer 390, lower surfaces of the via connection pattern portions 322 forming the first wiring layer L1 may be at the same vertical level as the upper surface of the cover resin layer 315, lower surfaces of the via connection pattern portions 322 forming the second wiring layer L2 may be at the same vertical level as the lower surface of the expanded base layer 310 in which the via connection pattern portions 322 forming the second wiring layer L2 are buried, and lower surfaces of the via connection pattern portions 322 forming the third wiring layer L3 may be at the same vertical level as the lower surface of the expanded base layer 310 in which the via connection pattern portions 322 forming the third wiring layer L3 are buried.

In one or more examples, the second interconnection structure 400 may include a second redistribution insulating layer 410 and a plurality of second redistribution patterns 420. The second redistribution patterns 420 may include a plurality of second redistribution line patterns 422, a plurality of second redistribution vias 424, and a plurality of second redistribution seed layers 426. The second redistribution insulating layer 410 and the second redistribution patterns 420 included in the second interconnection structure 400 may be substantially the same as the first redistribution insulating layer 210 and the first redistribution patterns 220 included in the first interconnection structure 200, and thus, redundant descriptions of the same configurations may be omitted.

In some embodiments, the thickness of the second interconnection structure 400 may be less than that of the first interconnection structure 200. For example, the thickness of the first interconnection structure 200 may be in a range of about 30 μm to about 50 μm, and the thickness of the second interconnection structure 400 may be less than that of the first interconnection structure 200 and in a range of about 20 μm to about 40 μm. In some embodiments, the second interconnection structure 400 may include a plurality of stacked second redistribution insulating layers 410. For example, the number of stacked second redistribution insulating layers 410 included in the second interconnection structure 400 may be less than the number of stacked first redistribution insulating layers 210 included in the first interconnection structure 200. The upper surface of the filling insulating layer 390 may be at the same vertical level as the lower surface of the second redistribution insulating layer 410.

In one or more examples, the second redistribution vias 424 may penetrate at least one second redistribution insulating layer 410 and respectively contact some of the second redistribution line patterns 422 and are connected thereto. In some embodiments, the second redistribution vias 424 may each have a tapered shape extending upwards from the lower portion thereof and increasing in horizontal width. For example, the second redistribution vias 424 may have the horizontal width increasing away from at least one semiconductor chip 100. The lowermost second redistribution vias 424 among the second redistribution vias 424 may be connected to the upper surface of the via structure 320. In some embodiments, the lowermost second redistribution vias 424 among the second redistribution vias 424 may penetrate the filling insulating layer 390 and be connected to the upper surface of the via structure 320.

In some embodiments, at least some of the second redistribution line patterns 422 may be formed together with some of the second redistribution vias 424 and integral. For example, the second redistribution line pattern 422 and the second redistribution via 424 contacting the lower surface of the second redistribution line pattern 422 (e.g., the second redistribution via 424 extending from the lower surface of the second redistribution line pattern 422), may be formed together as a single body. For example, each of the second redistribution vias 424 may have a horizontal width decreasing away from the second redistribution line pattern 422 that is formed integrally with the second redistribution via 424.

In one or more examples, the second redistribution seed layer 426 may extend under the second redistribution line pattern 422 and the second redistribution via 424 that are formed integrally with each other. For example, the second redistribution seed layer 426 may cover the lower surface of the second redistribution line pattern 422 and the side and lower surfaces of the second redistribution via 424 among the surfaces of the second redistribution line pattern 422 and the second redistribution via 424 that are formed integrally with each other. The second redistribution seed layer 426 may not cover the side and upper surfaces of the second redistribution line pattern 422. In some embodiments, the second redistribution seed layer 426 may be formed to be a portion of the second redistribution line pattern 422 or a portion of the second redistribution via 424. For example, when the second redistribution seed layer 426 is formed first and then the second redistribution line pattern 422 or the second redistribution via 424 contacting the second redistribution seed layer 426 is formed, the second redistribution line pattern 422 or the second redistribution via 424 contacting the second redistribution seed layer 426 may be formed integrally with the second redistribution seed layer 426 with an undifferentiated boundary. For example, a portion of the second redistribution seed layer 426 contacting the second redistribution line pattern 422 may be a portion of the second redistribution line pattern 422, and a portion of the second redistribution seed layer 426 contacting the second redistribution via 424 may be a portion of the second redistribution via 424.

The second interconnection structure 400 may include a plurality of upper surface connection pads PAD-U arranged on the upper surface of the second interconnection structure 400. In some embodiments, each of the upper surface connection pads PAD-U may include an upper surface connection pad layer 430 that covers a portion of the second redistribution line pattern 422 and an upper surface of the portion of the second redistribution line pattern 422. The upper surface connection pad layer 430 may include a first upper surface metal layer 432 and a second upper surface metal layer 434 which are sequentially stacked on the second redistribution line pattern 422. In some embodiments, the first upper surface metal layer 432 may include Ni, and the second upper surface metal layer 434 may include Au. However, as understood by one of ordinary skill in the art, the embodiments are not limited to these configurations, and may include any suitable metal known to one of ordinary skill in the art.

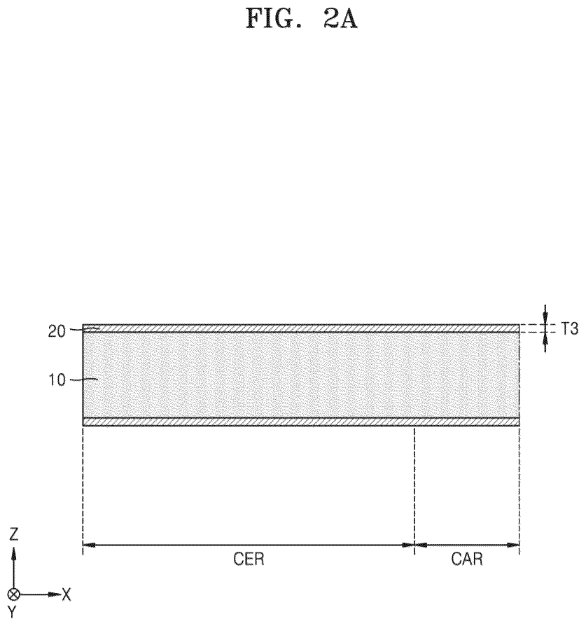

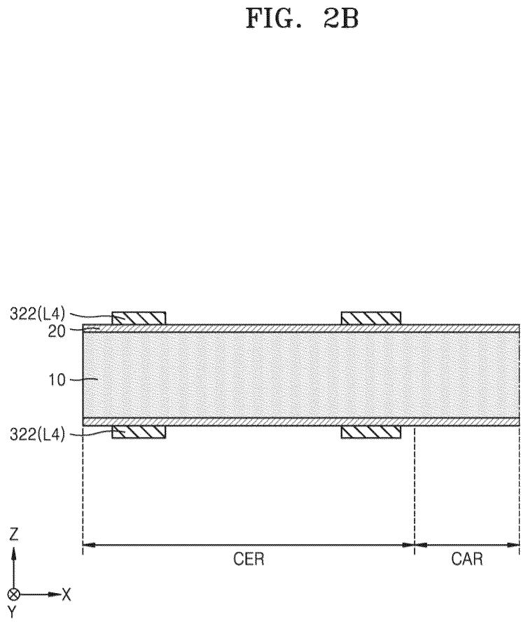

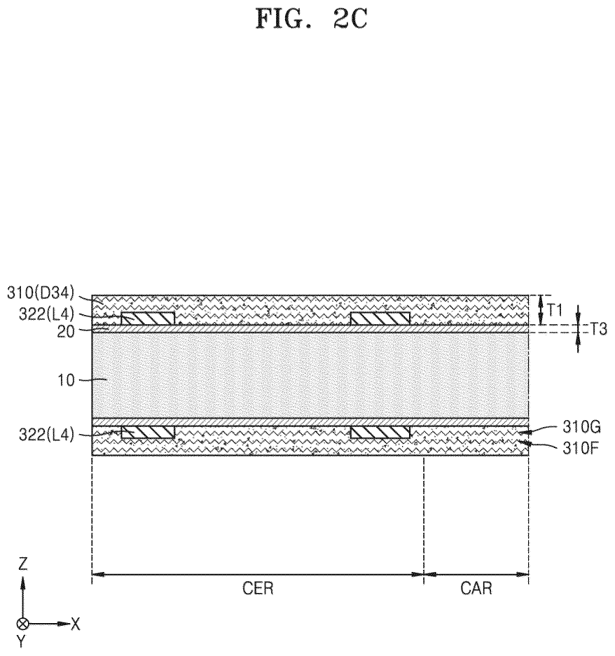

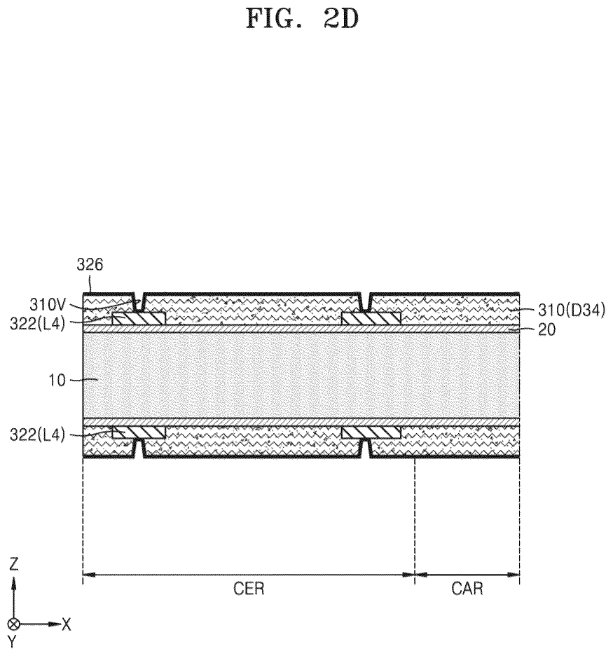

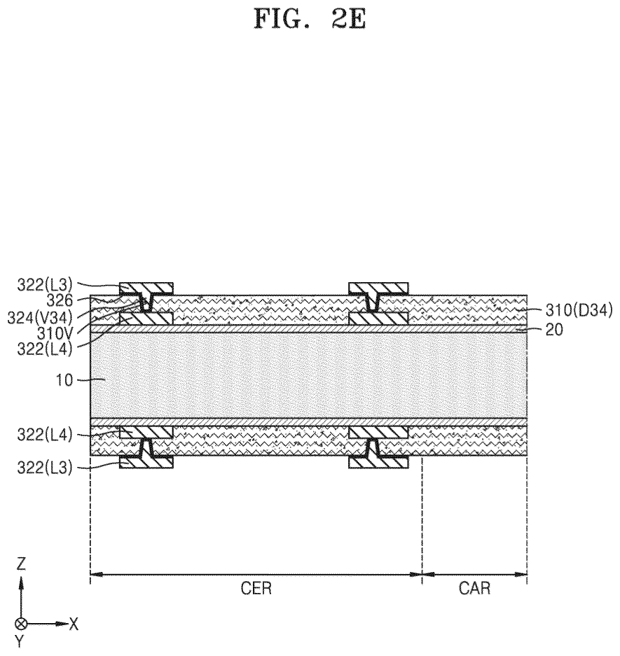

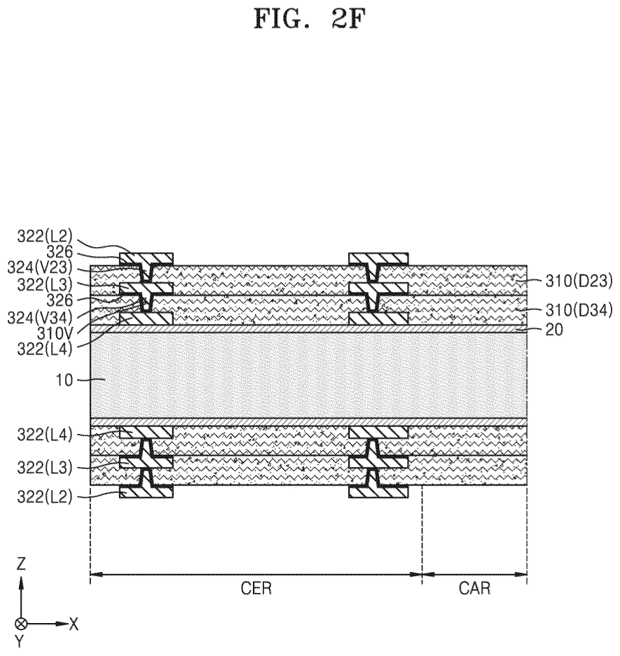

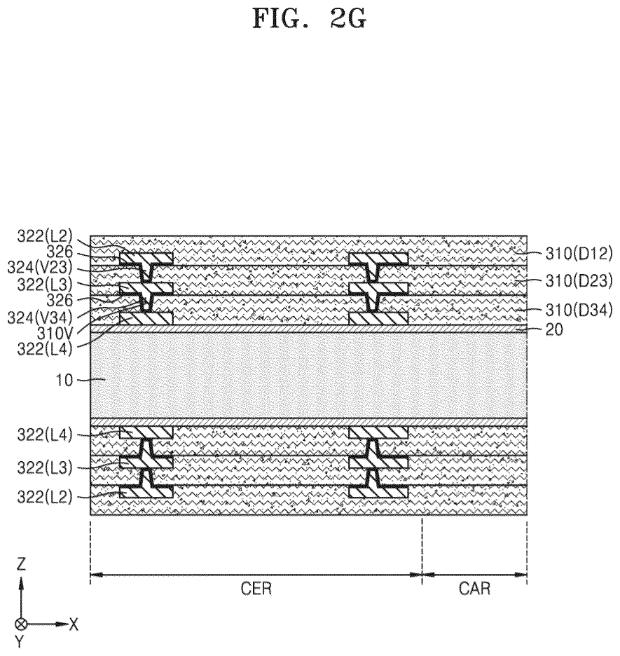

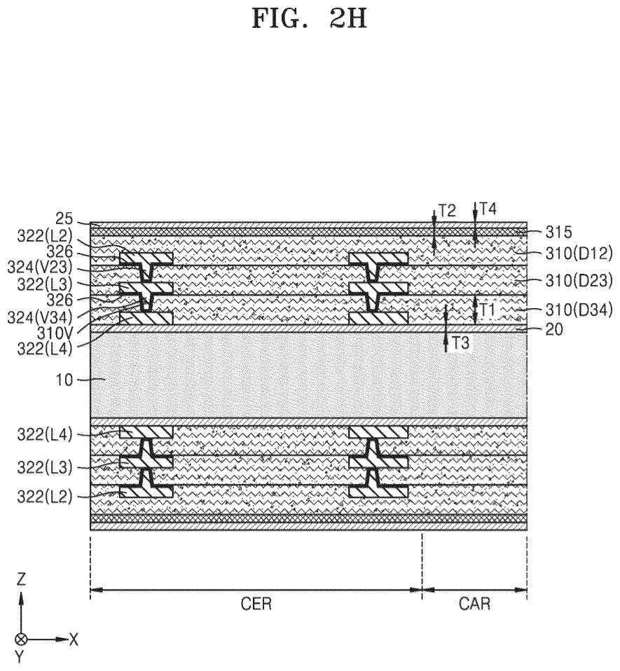

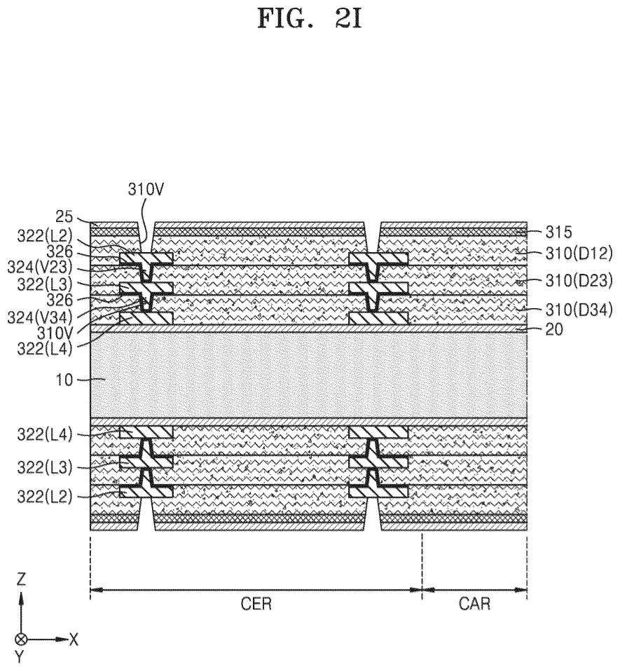

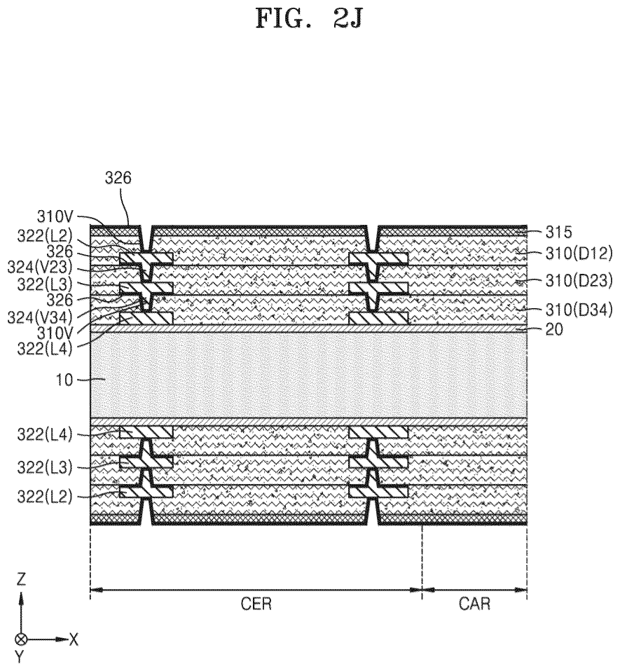

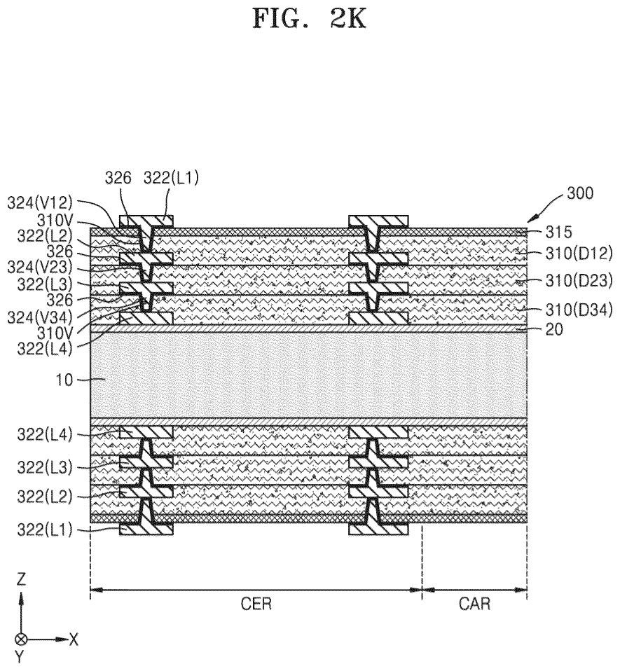

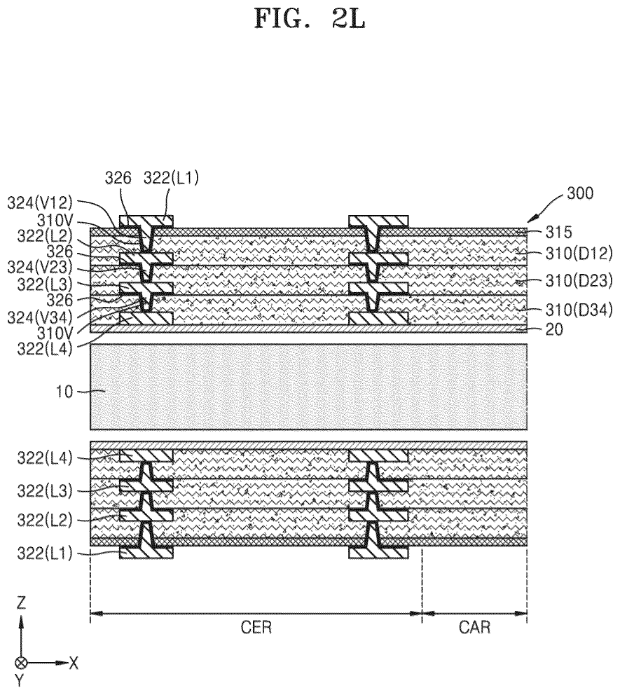

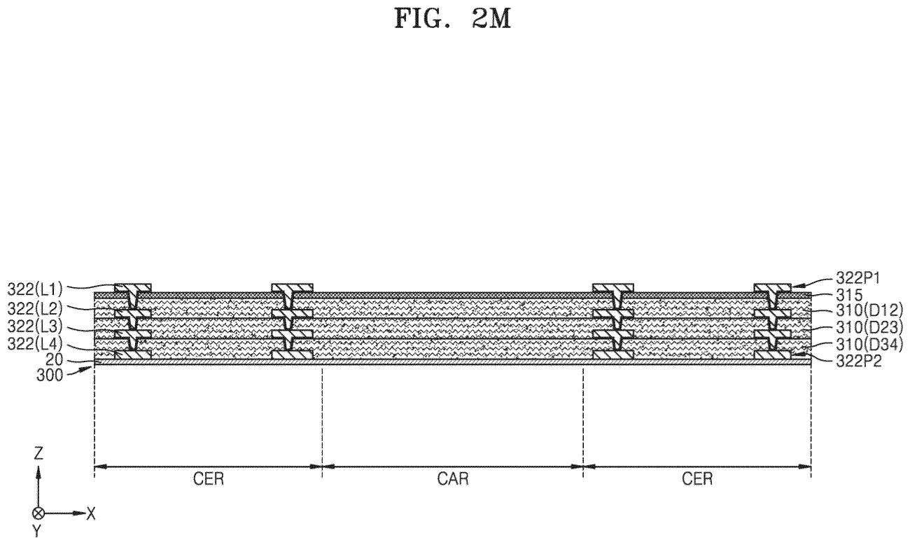

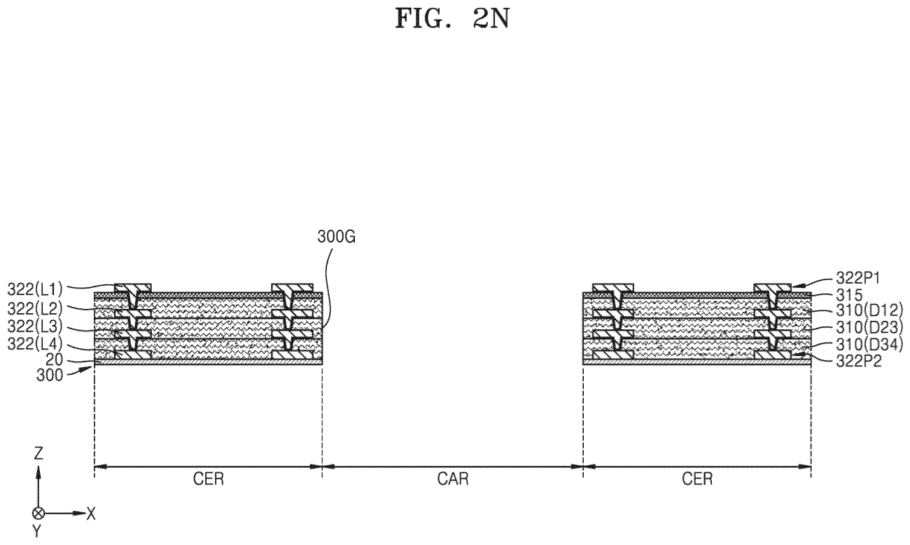

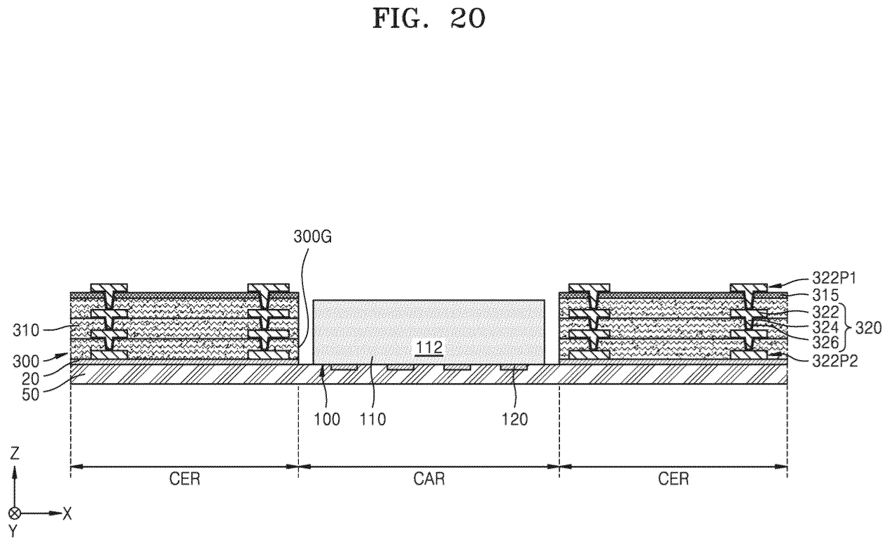

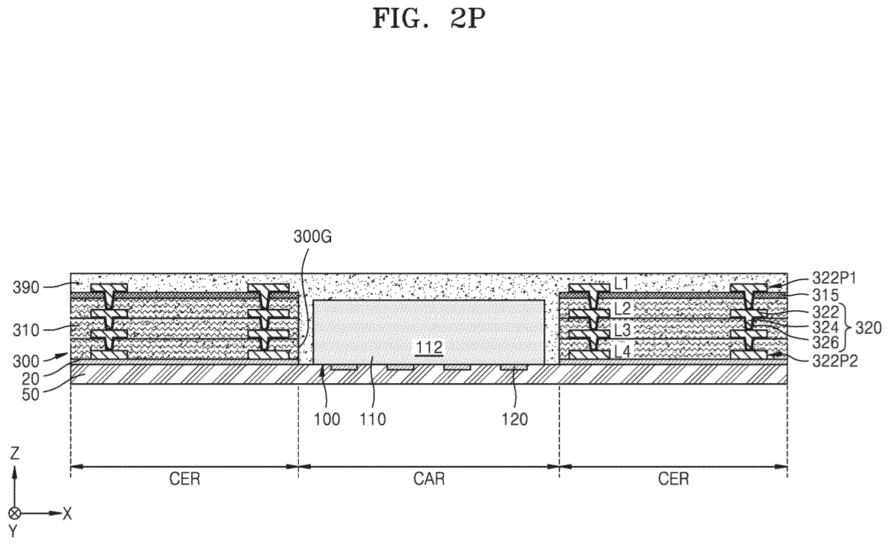

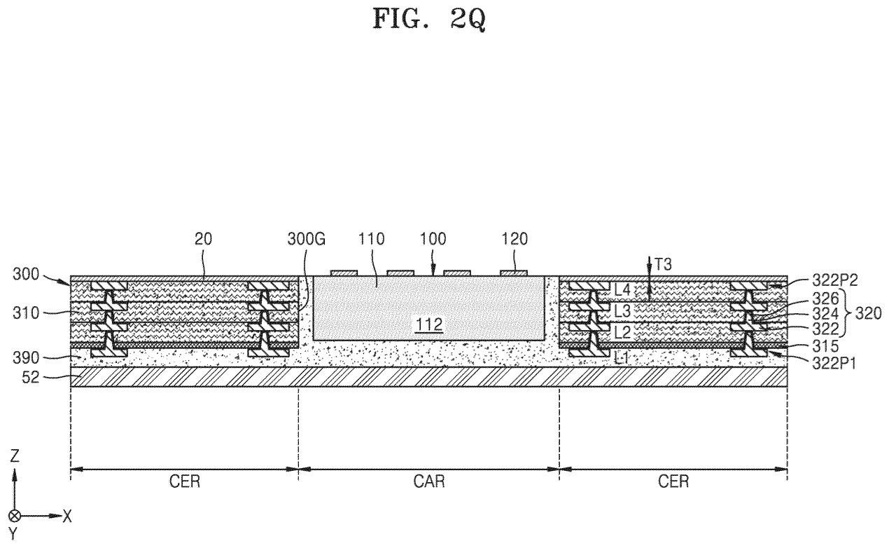

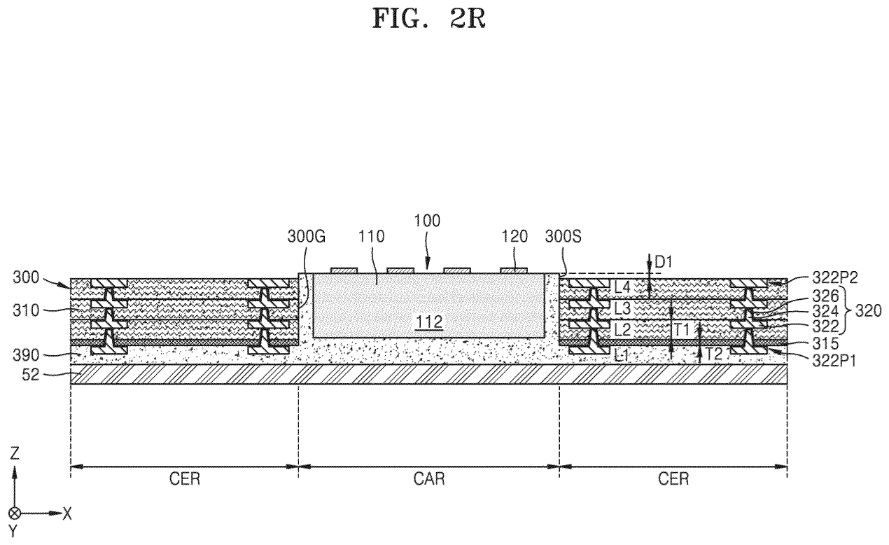

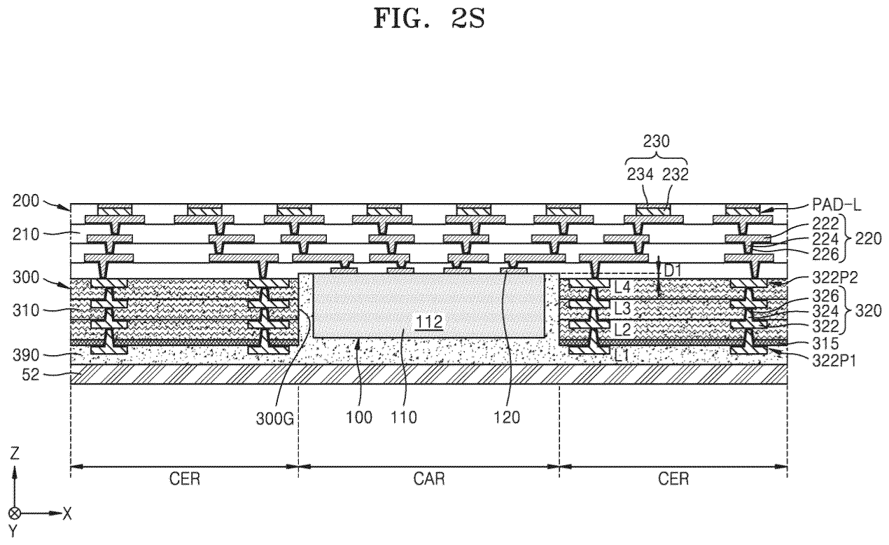

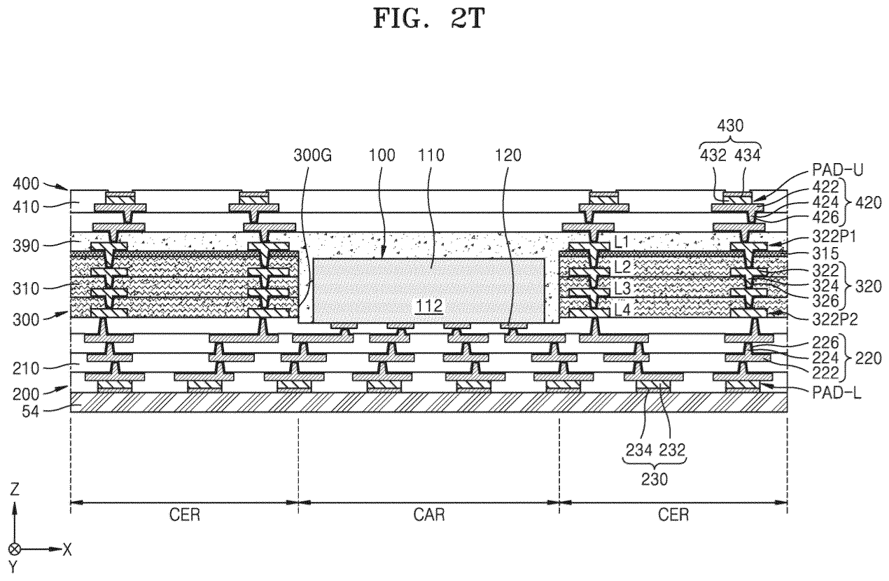

FIGS. 2A to 2T are cross-sectional views showing a method of manufacturing a semiconductor package that is an FOPLP, according to embodiments.

Referring to FIG. 2A, a first support substrate 10 is prepared, in which seed layers 20 are formed on both an upper surface and a lower surface of the first support substrate 10. The first support substrate 10 may include a chip accommodation region CAR and a chip peripheral region CER around the chip accommodation region CAR. In some embodiments, the first support substrate 10 may be a core layer or a prepreg layer including at least one of phenol resin, epoxy resin, and polyimide, a semiconductor substrate, a glass substrate, a ceramic substrate, or a plastic substrate. As understood by one of ordinary skill in the art, a prepreg layer may be a layer that has been pre-impregnated with a resin system that may include a curing agent. The seed layer 20 may include ED copper foil, RA copper foil, stainless steel foil, aluminum foil, ultra-thin copper foil, sputtered copper, copper alloys, or any other suitable material known to one of ordinary skill in the art. The seed layer 20 may have a third thickness T3. For example, the third thickness T3 may be in a range of about 2 μm to about 5 μm.

Referring to FIG. 2B, via connection pattern portions 322 are formed on the seed layer 20. The via connection pattern portions 322 may be the via connection pattern portions 322 constituting the fourth wiring layer LA of FIGS. 1A and 1B. In some embodiments, the via connection pattern portions 322 may be formed through a plating process, such as electroplating or electroless plating, during which the seed layer 20 is used as a seed. In some embodiments, after a mask pattern is formed on the seed layer 20 and a metal layer is formed through a plating process by using the seed layer 20 as a seed, a lift-off process may be performed to remove the mask pattern and a portion of the metal layer on the mask pattern, thereby forming the via connection pattern portions 322.

Referring to FIG. 2C, the expanded base layer 310 is formed on the via connection pattern portions 322 forming the fourth wiring layer L4 and the seed layer 20. The expanded base layer 310 may perform a function of an insulating layer D34 arranged between the via connection pattern portions 322 forming the third wiring layer L3 and the via connection pattern portions 322 forming the fourth wiring layer LA which are shown in FIGS. 1A and 1B. The expanded base layer 310 may cover all of the via connection pattern portions 322 forming the fourth wiring layer LA.

In some embodiments, the expanded base layer 310 may contain the first filler 310F. For example, the expanded base layer 310 may be in the form of a sheet made by impregnating the reinforced material 310G with a bonding material. The expanded base layer 310 may have the first thickness T1. The first thickness T1 may be greater than the third thickness T3. For example, the first thickness T1 may be in a range of about 20 μm to about 50 μm.

Referring to FIG. 2D, after a plurality of through holes 310V are formed by removing a portion of the expanded base layer 310, the via seed layer 326 is formed on the expanded base layer 310, in which the through holes 310V partially expose the via connection pattern portions 322 forming the fourth wiring layer L4. The via seed layer 326 may be formed to conformally cover the upper surface of the expanded base layer 310, surfaces of the expanded base layer 310 that are exposed to the side surfaces of the through holes 310V, and portions of the upper surfaces of the via connection pattern portions 322 that are exposed to the lower surfaces of the through holes 310V. For example, the via seed layer 326 may include Cu or Cu alloys.

Referring to FIG. 2E, the extended via portions 324, which fill the through holes 310V, and the via connection pattern portions 322, which are connected to the extended via portions 324 and arranged on the expanded base layer 310, are formed on the via seed layer 326. The via connection pattern portions 322, which are arranged on the expanded base layer 310, may be the via connection pattern portions 322 forming the third wiring layer L3 shown in FIGS. 1A and 1B. The extended via portions 324 filling the through holes 310V may perform the function of a connection via V34 that electrically connects the via connection pattern portions 322 forming the third wiring layer L3 and the via connection pattern portions 322 forming the fourth wiring layer L4.

Referring to FIG. 2F, the expanded base layer 310, which performs the function of an insulating layer D23 arranged between the via connection pattern portions 322 forming the second wiring layer L2 and the via connection pattern portions 322 forming the third wiring layer L3, the via connection pattern portions 322 forming the second wiring layer L3, and the extended via portions 324, which perform the function of a connection via V23 electrically connecting the via connection pattern portions 322 forming the second wiring layer L2 to the via connection pattern portions 322 forming the third wiring layer L3, are formed.

Referring to FIG. 2G, the expanded base layer 310 is formed, performing the function of an insulating layer D12 arranged between the via connection pattern portions 322 forming the first wiring layer L1 and the via connection pattern portions 322 forming the second wiring layer L2 which are shown in FIGS. 1A and 1B.

Referring to FIG. 2H, the cover resin layer 315 and a sub-seed layer 25 are sequentially formed on the uppermost expanded base layer 310. The cover resin layer 315 may include a resin including an organic material. The cover resin layer 315 may have the second thickness T2. The second thickness T2 may be less than the first thickness T1. For example, the second thickness T2 may be in a range of about 2 μm to about 7 μm. The second thickness T2 may be equal to or greater than the third thickness T3. The cover resin layer 315 may not include a filler and a reinforced material.

In some embodiments, the sub-seed layer 25 may be formed through a plating process, such as electroless plating. In some embodiments, the sub-seed layer 25 may be copper foil attached to the cover resin layer 315. The sub-seed layer 25 may include Cu or Cu alloys. The sub-seed layer 25 may have a fourth thickness T34. The fourth thickness T4 may be less than the third thickness T3. For example, the fourth thickness T4 may be in a range of about 1 μm to about 2 μm.

Referring to FIG. 2I, the through holes 310V are formed by removing portions of the sub-seed layer 25, the cover resin layer 315, and the uppermost expanded base layer 310, in which the through holes 310V expose portions of the via connection pattern portions 322 constituting the second wiring layer L2.

Referring to FIGS. 2I and 2J, after the portions of the sub-seed layer 25 is removed, the via seed layer 326 is formed on the cover resin layer 315 and the uppermost expanded base layer 310. The via seed layer 326 may be formed to conformally cover the upper surface of the cover resin layer 315, the surfaces of the cover resin layer 315 and the surfaces of the uppermost expanded base layer 310, which are exposed to the side surfaces of the through holes 310V, and portions of the upper surfaces of the via connection pattern portions 322 forming the second wiring layer L2, which are exposed to the lower surfaces of the through holes 310V. The cover resin layer 315 and the uppermost expanded base layer 310 may function as insulating layers arranged between the via connection pattern portions 322 forming the first wiring layer L1 and the via connection pattern portions 322 forming the second wiring layer L2.

Referring to FIG. 2K, the extended via portions 324, which fill the through holes 310V, and the via connection pattern portions 322, which are connected to the extended via portions 324 and arranged on the expanded base layer 310, are formed on the via seed layer 326, thereby forming the expanded layer 300 on each of the upper surface and the lower surface of the first support substrate 10. The via connection pattern portions 322 arranged on the uppermost expanded base layer 310 may be the via connection pattern portions 322 constituting the first wiring layer L1. The extended via portions 324 filling the through holes 310V may perform the function of a connection via V12 that electrically connects the via connection pattern portions 322 forming the first wiring layer L1 and the via connection pattern portions 322 forming the second wiring layer L2.

Referring to FIGS. 2L and 2M, in one or more examples, the expanded layer 310 is separated from each of the upper surface and the lower surface of the first support substrate 10. When the expanded layer 300 is separated from each of the upper surface and the lower surface of the first support substrate 10, the seed layer 20 may be separated from the first support substrate 10 together with the expanded layer 300 while remaining attached to the expanded layer 300.

Each of the via connection pattern portions 322 forming the first wiring layer L1 may be the upper surface expanded connection pad 322P1, and each of the via connection pattern portions 322 forming the fourth wiring layer L4 may be the lower surface expanded connection pad 322P2.

Referring to FIGS. 2M and 2N together, the mounting space 300G penetrating the expanded layer 300 is formed. The mounting space 300G may be formed by removing a portion of the expanded layer 300 that is located in the chip accommodation region CAR, for example, a portion of the cover resin layer 315 and portions of the expanded base layer 310.

Referring to FIG. 20, after the expanded layer 300 is attached to a second support substrate 50, the semiconductor chip 100 accommodated in the mounting space 300G is attached to the second support substrate 50. The semiconductor chip 100 may be attached to the second support substrate 50 to make the chip pads 120 face the second support substrate 50. The second support substrate 50 may be a semiconductor substrate, a glass substrate, a ceramic substrate, or a plastic substrate. In some embodiments, an adhesive layer may be on an upper portion of the second support substrate 50. The semiconductor chip 100 may be attached to the second support substrate 50 to make the chip pads 120 buried in the adhesive layer.

Referring to FIG. 2P, the filling insulating layer 390 is formed, filling the mounting space 300G and covering the upper surface of the expanded layer 300 and the upper surface of the semiconductor chip 100. The filling insulating layer 390 may fill a gap between the expanded base layer 310 and the semiconductor chip 100 arranged in the mounting space 300G.

Referring to FIGS. 2P and 2Q together, after the expanded layer 300, the semiconductor chip 100, and the filling insulating layer 390 are separated from the second support substrate 50, a result including the expanded layer 300, the semiconductor chip 100, and the filling insulating layer 390 is flipped vertically and attached to a third support substrate 52. The filling insulating layer 390 may contact the third support substrate 52. Referring to FIGS. 2Q and 2R together, a sink space 300S is formed by removing the seed layer 20 from the expanded layer 300, in which the sink space 300S is defined by the expanded layer 300 and the filling insulating layer 390. For example, the sink space 300S may be formed to have a sink depth D1 of about 2 μm to about 5 μm, compared to the upper surface of the filling insulating layer 390.

Referring to FIG. 2S, the first interconnection structure 200 including the first redistribution insulating layer 210 and the first redistribution patterns 220 is formed on the expanded layer 300, the semiconductor chip 100, and the filling insulating layer 390. The first interconnection structure 200 may be formed on the expanded layer 300, the semiconductor chip 100, and the filling insulating layer 390 to electrically connect the first redistribution patterns 220 to the chip pads 120 and the via structures 320. The sink space 300S may be filled by the lowermost first redistribution insulating layer 210 and a lower portion of each of the lowermost first redistribution vias 224.

Referring to FIGS. 2S and 2T together, after the third support substrate 52 is separated from the filling insulating layer 390, the result including the expanded layer 300, the semiconductor chip 100, the filling insulating layer 390, and the first interconnection structure 200 is flipped vertically and attached to a fourth support substrate 54. The first interconnection structure 200 may contact the fourth support substrate 54.

In the subsequent operation, the second interconnection structure 400 including the second redistribution insulating layer 410 and the second redistribution patterns 420 are formed on the filling insulating layer 390. The lowermost second redistribution vias 424 among the second redistribution vias 424 included in the second redistribution patterns 420 may penetrate the filling insulating layer 390 and be connected to the upper surface of the via structure 320.

Subsequently, after the fourth support substrate 54 is separated from the first interconnection structure 200, the external connection terminals 500 are attached to the lower surface of the first interconnection structure 200 as shown in FIG. 1, thus forming the semiconductor package 1.

Referring to FIGS. 1A to 2T together, in the semiconductor package 1, because the seed layer 20 is removed and the first interconnection structure 200 is formed after the formation of the mounting space 300G and the filling insulating layer 390, the delamination between the lower surface expanded connection pad 322P2 and the lowermost expanded base layer 310 may be prevented, and the roughness on the lower surface of the lower surface expanded connection pad 322P2 may be reduced, thereby preventing the generation of cracks in the lower surface expanded connection pad 322P2.

Therefore, in the semiconductor package 1 according to one or more embodiments, the electrical connection reliability between the expanded layer 300 and the first interconnection structure 200, for example, the lower surface expanded connection pad 322P2 and the first redistribution via 224, may be improved, and the via structures 320 and the first redistribution patterns 220 may be realized as fine patterns.

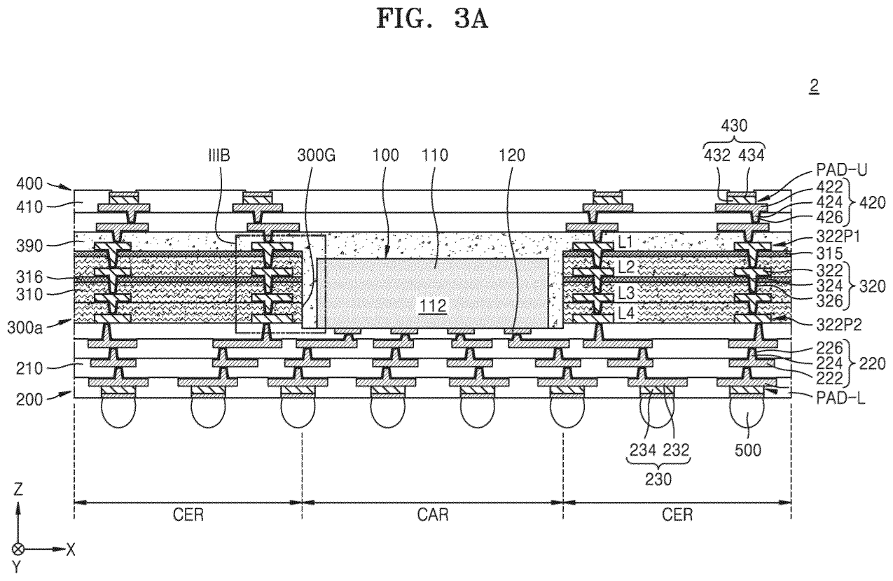

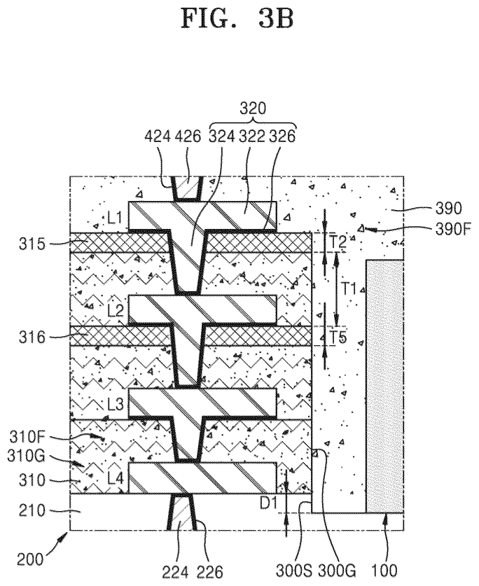

FIGS. 3A and 3B are cross-sectional views of a semiconductor package, which may be an FOPLP, according to embodiments. In detail, FIG. 3B is a cross-sectional view showing an enlarged region IIIB of FIG. 3A.

Referring to FIGS. 3A and 3B together, a semiconductor package 2 may include a first interconnection structure 200, a second interconnection structure 400 on the first interconnection structure 200, at least one semiconductor chip 100 arranged between the first interconnection structure 200 and the second interconnection structure 400, and an expanded layer 300a arranged between the first interconnection structure 200 and the second interconnection structure 400 and encircling the surroundings of the at least one semiconductor chip 100. The expanded layer 300a may be configured to electrically connect the first interconnection structure 200 to the second interconnection structure 400. In some embodiments, the semiconductor package 2 may be an FOPLP. The semiconductor package 2 includes the expanded layer 300a instead of the expanded layer 300 included in the semiconductor package 1 of FIGS. 1A and 1B.

The expanded layer 300a may include an expanded base layer 310 and a plurality of via structures 320. The expanded layer 300a may include a mounting space 300G where at least one semiconductor chip 100 is arranged. The via structures 320 may penetrate from the upper surface of the expanded base layer 310 to the lower surface thereof. The expanded layer 300a may be an ETS, a PCB, a ceramic substrate, a wafer for manufacturing a package, or an interposer. In some embodiments, the expanded layer 300a may include at least two stacked expanded base layers 310.

The mounting space 300G may be formed as an opening or a cavity in the expanded layer 300a. The mounting space 300G may be formed in some regions of the expanded layer 300a, for example, a central region of the expanded layer 300a in the plan view. The mounting space 300G may be formed to penetrate from the upper surface of the expanded layer 300a to the lower surface thereof.

The expanded layer 300a may further include a cover resin layer 315 and at least one inner cover resin layer 316. The cover resin layer 315 may cover an upper surface of the uppermost expanded base layer 310, and the at least one inner cover resin layer 316 may cover an upper surface of at least one expanded base layer 310 from the second upper portion. At least one inner cover resin layer 316 may not cover the upper surface of at least one expanded base layer 310 from the lowermost portion. The cover resin layer 315 and the at least one inner cover resin layer 316 may be referred to as at least two cover resin layers or as a first cover resin layer and a second cover resin layer, respectively. For example, the expanded layer 300a may include the at least two cover resin layers including the first cover resin layer and the second cover resin layer.

FIGS. 3A and 3B show that the expanded layer 300a includes three stacked expanded base layers 310 and that the inner cover resin layer 316 covers the upper surface of the second uppermost expanded base layer 310 that is located second from the uppermost portion and does not cover the upper surface of the lowermost expanded base layer 310, but one or more embodiments are not limited thereto. For example, the expanded layer 300a may include at least four stacked expanded base layers 310, and the at least two cover resin layers may cover the upper surface of each of at least two expanded base layers 310 except at least one expanded base layer 310 from the lowermost portion among the at least four stacked expanded base layers 310.

The cover resin layer 315 and the inner cover resin layer 316 may include substantially the same materials and be formed through substantially the same manufacturing processes. Similar to the manufacturing processes for the cover resin layer 315 of FIG. 2Q, for example, the inner cover resin layer 316 may be formed to cover the upper surface of at least one expanded base layer 310 from the second uppermost portion. For example, the extended via portions 324 connected to the lower surfaces of the via connection pattern portions 322 forming the second wiring layer L2 may be formed to penetrate the inner cover resin layer 316 and the second uppermost expanded base layer 310. The inner cover resin layer 316 may have a fifth thickness T5. The fifth thickness T5 may be substantially the same as the second thickness T2. For example, the fifth thickness T5 may be in a range of about 2 μm to about 7 μm. The inner cover resin layer 316 may not include a filler and a reinforced material.

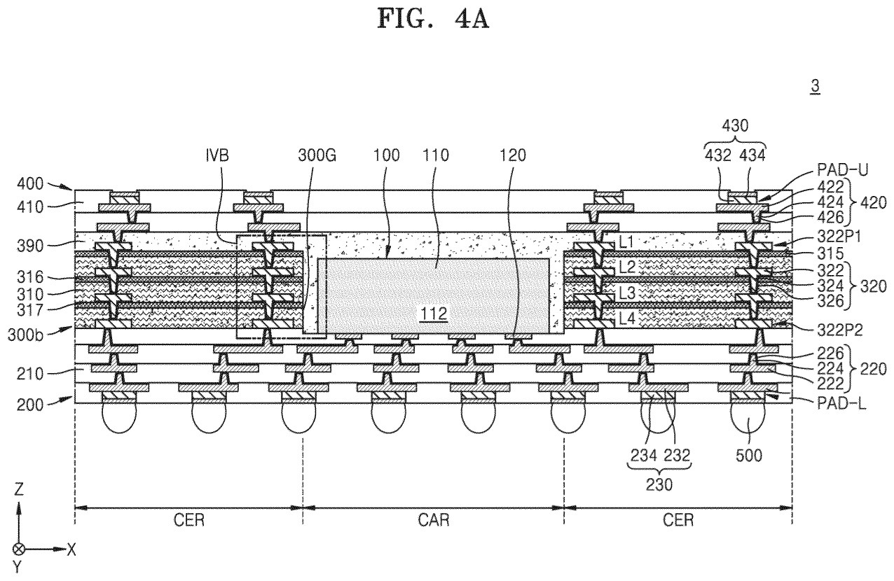

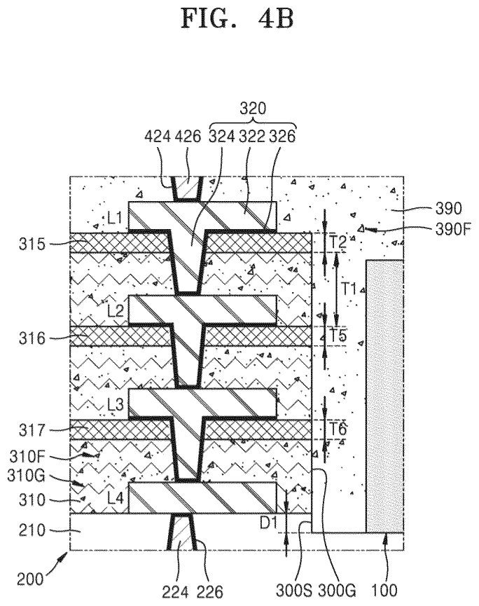

FIGS. 4A and 4B are cross-sectional views of a semiconductor package that is an FOPLP, according to embodiments. In detail, FIG. 4B is a cross-sectional view showing an enlarged region IVB of FIG. 4A.

Referring to FIGS. 4A and 4B together, a semiconductor package 3 may include a first interconnection structure 200, a second interconnection structure 400 on the first interconnection structure 200, at least one semiconductor chip 100 arranged between the first interconnection structure 200 and the second interconnection structure 400, and an expanded layer 300b arranged between the first interconnection structure 200 and the second interconnection structure 400 and encircling the surroundings of the at least one semiconductor chip 100. The expanded layer 300b may be configured to electrically connect the first interconnection structure 200 to the second interconnection structure 400. In some embodiments, the semiconductor package 3 may be an FOPLP. The semiconductor package 3 may include the expanded layer 300b instead of the expanded layer 300 included in the semiconductor package 1 of FIGS. 1A and 1B.

The expanded layer 300b may include an expanded base layer 310 and a plurality of via structures 320. The expanded layer 300b may include a mounting space 300G where at least one semiconductor chip 100 is arranged. The via structures 320 may penetrate from the upper surface of the expanded base layer 310 to the lower surface thereof. The expanded layer 300b may be an ETS, a PCB, a ceramic substrate, a wafer for manufacturing a package, or an interposer. In some embodiments, the expanded layer 300b may include stacked expanded base layers 310.

The mounting space 300G may be formed as an opening or a cavity in the expanded layer 300b. The mounting space 300G may be formed in some regions of the expanded layer 300b, for example, a central region of the expanded layer 300b in the plan view. The mounting space 300G may be formed to penetrate from the upper surface of the expanded layer 300b to the lower surface thereof.

The expanded layer 300b may further include the cover resin layer 315, a first inner cover resin layer 316, and a second inner cover resin layer 317. The cover resin layer 315 may cover the upper surface of the uppermost expanded base layer 310, and the first inner cover resin layer 316 and the second inner cover resin layer 317 may cover the upper surfaces of remaining expanded base layers 310 except the uppermost expanded base layer 310 among the expanded base layers 310. For example, the cover resin layer 315, the first inner cover resin layer 316, and the second inner cover resin layer 317 may cover the upper surfaces of the expanded base layer 310. For example, the cover resin layer 315, the first inner cover resin layer 316, and the second inner cover resin layer 317 may be referred to as a plurality of cover resin layers or as a first cover resin layer, a second cover resin layer, and a third cover resin layer, respectively. For example, the expanded layer 300b may include the cover resin layers corresponding to the expanded base layers 310. In other words, the lowermost cover resin layer among the cover resin layers, for example, the second inner cover resin layer 317, may cover the upper surface of the lowermost expanded base layer 310.

The cover resin layer 315, the first inner cover resin layer 316, and the second inner cover resin layer 317 may include substantially the same material and be formed through substantially the same manufacturing processes. Similar to the manufacturing processes for the cover resin layer 315 of FIG. 2Q, for example, the first inner cover resin layer 316 and the second inner cover resin layer 317 may be formed to cover the upper surfaces of the remaining expanded base layers 310 except the uppermost expanded base layer 310 among the expanded base layers 310. For example, the extended via portions 324 connected to the lower surfaces of the via connection pattern portions 322 forming the second wiring layer L2 may be formed to penetrate the first inner cover resin layer 316 and the second uppermost expanded base layer 310. For example, the extended via portions 324 connected to the lower surfaces of the via connection pattern portions 322 forming the third wiring layer L3 may be formed to penetrate the second inner cover resin layer 317 and the lowermost expanded base layer 310.

The first inner cover resin layer 316 may have a fifth thickness T5, and the second inner cover resin layer 317 may have a sixth thickness T6. In one or more examples, each of the fifth thickness T5 and the sixth thickness T6 may be substantially the same as the second thickness T2. For example, each of the fifth thickness T5 and the sixth thickness T6 may be in a range of about 2 μm to about 7 μm. Each of the first inner cover resin layer 316 and the second inner cover resin layer 317 may not include a filler and a reinforced material.

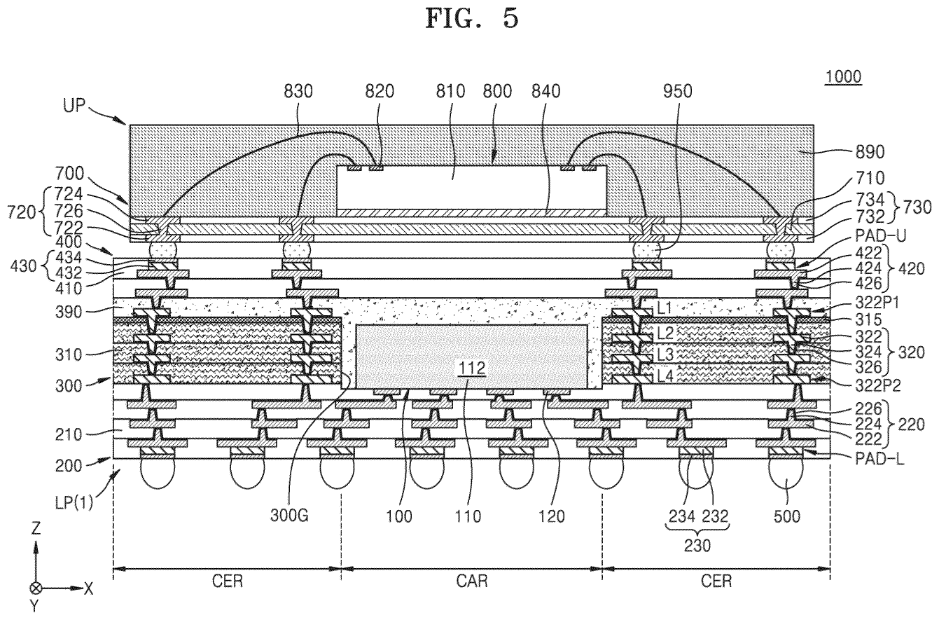

FIG. 5 is a cross-sectional view of a semiconductor package that is a package-on-package, according to embodiments.

Referring to FIG. 5, a semiconductor package 1000 may be a package-on-package in which an upper package UP is attached to a lower package LP. The lower package LP may be the semiconductor package 1 of FIG. 1A. In some embodiments, the semiconductor package 1000 may include, as the lower package LP, the semiconductor package 2 of FIG. 3A or the semiconductor package 3 of FIG. 4A instead of including the semiconductor package 1 of FIG. 1A.

The lower package LP may include the first interconnection structure 200, the expanded layer 300 with the mounting space 300G on the first interconnection structure 200, at least one semiconductor chip 100 accommodated in the mounting space 300G, the filling insulating layer 390 filling the mounting space 300G and covering the at least one semiconductor chip 100 and the expanded layer 300, and the second interconnection structure 400 on the filling insulating layer 390. The expanded layer 300 may include the expanded base layer 310, the cover resin layer 315, and the via structures 320.

The upper package UP may be attached to the second interconnection structure 400. The upper package UP may be electrically connected to the second redistribution patterns 420 of the second interconnection structure 400. For example, the upper package UP may be connected to upper surface connection pads PAD-U. For example, a plurality of package connection terminals 950 may be between the upper package UP and the upper surface connection pads PAD-U. For example, the package connection terminals 950 may be attached to a plurality of upper surface connection pad layers 430. The package connection terminals 950 may be configured to electrically connect the lower package LP to the upper package UP. In some embodiments, each of the package connection terminals 950 may be a bump, a solder ball, or any other suitable material known to one of ordinary skill in the art.

The upper package UP includes a package substrate 700 and an auxiliary semiconductor chip 800 mounted on the package substrate 700. The auxiliary semiconductor chip 800 may include an auxiliary semiconductor substrate 810 including an active surface and an inactive surface that are opposite to each other, an auxiliary semiconductor device 812 formed on the active surface of the auxiliary semiconductor substrate 810, and a plurality of auxiliary chip pads 820 arranged on a third surface of the auxiliary semiconductor chip 800. The third surface of the auxiliary semiconductor chip 800 is opposite to a fourth surface of the auxiliary semiconductor chip 800, and the fourth surface of the auxiliary semiconductor chip 800 refers to the inactive surface of the auxiliary semiconductor substrate 810. The active surface of the auxiliary semiconductor substrate 810 is highly close to the third surface of the auxiliary semiconductor substrate 800. However, as understood by one of ordinary skill in the art, there may be separation between the active surface of the auxiliary semiconductor substrate 810 from the third surface of the auxiliary semiconductor chip 800 is omitted.

The auxiliary semiconductor chip 800 may be a memory semiconductor chip. For example, the auxiliary semiconductor chip 800 may be a DRAM chip, an SRAM chip, a flash memory chip, an erasable programmable ROM (EEPROM) chip, a PRAM chip, an MRAM chip, or an RRAM chip. The auxiliary semiconductor substrate 810 and the auxiliary chip pad 820 are similar to the semiconductor substrate 110 and the chip pad 120, and thus, detailed descriptions thereof are omitted. The semiconductor chip 100, the semiconductor substrate 110, the semiconductor device 112, and the chip pad 120 may be referred to as a first semiconductor chip, a first semiconductor substrate, a first semiconductor device, and a first chip pad or as a lower semiconductor chip, a lower semiconductor substrate, a lower semiconductor device, and a lower chip pad, and the auxiliary semiconductor chip 800, the auxiliary semiconductor substrate 810, the auxiliary semiconductor device 812, and the auxiliary chip pad 820 may be referred to as a second semiconductor chip, a second semiconductor substrate, a second semiconductor device, and a second chip pad or as an upper semiconductor chip, an upper semiconductor substrate, an upper semiconductor device, and an upper chip pad.

In some embodiments, the auxiliary semiconductor chip 800 may be electrically connected to the package substrate 700 through a plurality of bonding wires 830 connected to the auxiliary chip pads 820 and mounted on the package substrate 700 by using a die attach film (DAF) 840. In some embodiments, the upper package UP may include a plurality of auxiliary semiconductor chips 800 that are spaced apart from each other in a horizontal direction and a plurality of auxiliary semiconductor chips 800 that are stacked in a vertical direction. In one or more examples, the upper package UP may include a plurality of auxiliary semiconductor chips 800 that are electrically connected through a through electrode and vertically stacked. In one or more examples, the auxiliary semiconductor chip 800 may be mounted on the package substrate 700 in a flip-chip manner.

The package substrate 700 may be a PCB. For example, the package substrate 700 may be a double-sided PCB or a multi-layer PCB. The package substrate 700 may include at least one base insulating layer 710 and a plurality of wire patterns 720. The wire patterns 720 may include a plurality of lower surface conductive patterns 722, a plurality of upper surface conductive patterns 724, and a plurality of via patterns 724. The lower surface conductive patterns 722 may be arranged on the lower surface of the base insulating layer 710, the upper surface conductive patterns 724 may be arranged on the upper surface of the base insulating layer 710, and the via patterns 724 may penetrate the base insulating layer 710 and connect the lower surface conductive patterns 722 to the upper surface conductive patterns 724. The base insulating layer 710 and the wire patterns 720 are substantially similar to the expanded base layer 310 and the via structures 320, and thus, detailed descriptions thereof are omitted. FIG. 9 shows that the package substrate 700 includes one base insulating layer 710, but this is merely an example. One or more embodiments are not limited thereto. For example, the package substrate 700 may include at least two stacked base insulating layers 710 and further include conductive patterns respectively arranged between the at least two base insulating layers 710.

In some embodiments, the package substrate 700 may include solder resist layers 730 arranged on upper and lower surfaces of the base insulating layer 710. The solder resist layer 730 may include a lower surface solder resist layer 732 arranged on the lower surface of the base insulating layer 710 and an upper surface solder resist layer 734 arranged on the upper surface of the base insulating layer 710. The lower surface conductive patterns 722 of the wire patterns 720 may not be covered by the lower surface solder resist layer 732 and may be exposed on the lower surface of the package substrate 700, while the upper surface conductive patterns 724 of the wire patterns 720 may not be covered by the upper surface solder resist layer 734 and may be exposed on the upper surface of the package substrate 700.

The package connection terminals 950 may be attached to the lower surface conductive patterns 722, and the bonding wires 830 may be connected to the upper surface conductive patterns 724.

In some embodiments, the upper package UP may further include, on the package substrate 700, a package molding layer 890 surrounding the auxiliary semiconductor chip 800 and the bonding wires 830. For example, the package molding layer 890 may include a molding member including an EMC.

While the embodiments of the present disclosure has been particularly shown and described with reference to embodiments thereof, it will be understood that various changes in form and details may be made therein without departing from the spirit and scope of the following claims.

What is claimed is:

1. A semiconductor package comprising:
a first interconnection structure;
an expanded layer arranged on the first interconnection structure, the expanded layer comprising a plurality of expanded base layers, a cover resin layer covering a surface of at least one expanded base layer from an uppermost portion among the plurality of expanded base layers, a plurality of via structures penetrating the plurality of expanded base layers and the cover resin layer, and a mounting space penetrating the plurality of expanded base layers;
a semiconductor chip arranged in the mounting space and electrically connected to the first interconnection structure;
a filling insulating layer configured to fill the mounting space; and
a second interconnection structure arranged on the expanded layer and the filling insulating layer, the second interconnection structure electrically connected to the first interconnection structure through the plurality of via structures,
wherein a surface of a lowermost expanded base layer among the plurality of expanded base layers is positioned at a higher vertical level than a surface of the filling insulating layer, and a sink space is confined by the expanded layer and the filling insulating layer under the surface of the lowermost expanded base layer among the plurality of expanded base layers.

2. The semiconductor package of claim 1, wherein the sink space is filled with a portion of the first interconnection structure.

3. The semiconductor package of claim 1, wherein each of the plurality of expanded base layers comprises a reinforced material and a first resin, wherein the reinforced material is glass cloth, carbon cloth, non-woven glass fabric, or aramid cloth, and
wherein the cover resin layer of the expanded layer comprises a second resin and does not comprise a reinforced material.

4. The semiconductor package of claim 1, wherein the plurality of expanded base layers and the filling insulating layer each comprise a first resin containing a filler, and
wherein the cover resin layer comprises a second resin and does not comprise a filler.

5. The semiconductor package of claim 1, wherein at least two cover resin layers are provided to respectively cover surfaces of at least two expanded base layers from among the plurality of expanded base layers.

6. The semiconductor package of claim 1, wherein the expanded layer further comprises a plurality of cover resin layers to cover a surface of each of the plurality of expanded base layers.

7. The semiconductor package of claim 1, wherein the plurality of via structures comprise a plurality of via connection pattern portions and a plurality of extended via portions connecting two via connection pattern portions that are positioned at different vertical levels among the plurality of via connection pattern portions,
wherein at least one of the plurality of via connection pattern portions is arranged on a surface of the cover resin layer, and
wherein at least one of the plurality of extended via portions penetrates one of the plurality of expanded base layers and the cover resin layer covering the one expanded base layer.

8. The semiconductor package of claim 7, wherein an uppermost via connection pattern portion among the plurality of via connection pattern portions protrudes upwards from the surface of the cover resin layer covering a surface of an uppermost expanded base layer from the plurality of expanded base layers, and wherein a lowermost via connection pattern portion among the plurality of via connection pattern portions is buried in the lowermost expanded base layer among the plurality of expanded base layers.

9. The semiconductor package of claim 8, wherein one or more surfaces of the lowermost via connection pattern portions among the plurality of via connection pattern portions and a surface of the lowermost expanded base layer among the plurality of expanded base layers are positioned at a same vertical level and are coplanar.

10. The semiconductor package of claim 7, wherein each of the plurality of extended via portions has a tapered shape with a horizontal width decreasing and extending in a direction towards the first interconnection structure from the second interconnection structure.

11. A semiconductor package comprising:
a first interconnection structure comprising a first redistribution insulating layer, a plurality of first redistribution line patterns arranged on at least one of a first surface and a second surface of the first redistribution insulating layer, and a plurality of first redistribution vias penetrating the first redistribution insulating layer and respectively connected to one or more of the plurality of first redistribution line patterns;
an expanded layer arranged on the first interconnection structure, the expanded layer comprising a plurality of expanded base layers, a cover resin layer covering a surface of at least one of the plurality of expanded base layers from an uppermost portion among the plurality of expanded base layers, a plurality of via structures penetrating the cover resin layer and the plurality of expanded base layers and respectively connected to one or more of the plurality of first redistribution vias, and a mounting space penetrating the plurality of expanded base layers;
a semiconductor chip arranged in the mounting space and comprising a plurality of chip pads connected to a respective first redistribution via from the plurality of first redistribution vias;
a filling insulating layer configured to fill the mounting space and cover a surface of the semiconductor chip and a surface of the expanded layer; and
a second interconnection structure arranged on the filling insulating layer, the second interconnection structure comprising a second redistribution insulating layer, a plurality of second redistribution line patterns arranged on at least one of a first surface and a second surface of the second redistribution insulating layer, and a plurality of second redistribution vias penetrating the second redistribution insulating layer and respectively connected to one or more of the plurality of second redistribution line patterns, the second interconnection structure being electrically connected to the first interconnection structure through the plurality of via structures,
wherein a surface of a lowermost expanded base layer among the plurality of expanded base layers is positioned at a higher vertical level than a surface of the filling insulating layer, and a sink space is confined by the expanded layer and the filling insulating layer under the surface of the lowermost expanded base layer among the plurality of expanded base layers, and
wherein the sink space is filled with a portion of the first redistribution insulating layer and portions of an uppermost first redistribution via among the plurality of first redistribution vias.

12. The semiconductor package of claim 11, wherein a portion of the first surface of the first redistribution insulating layer contacting the expanded layer is positioned at a higher vertical level than a portion of the first surface of the first redistribution insulating layer contacting the surface of the filling insulating layer.

13. The semiconductor package of claim 12, wherein the plurality of chip pads protrude from a surface of the semiconductor chip and are buried in the first redistribution insulating layer.

14. The semiconductor package of claim 11, wherein a thickness of the cover resin layer is less than a thickness of each of the plurality of expanded base layers.

15. The semiconductor package of claim 11, wherein each of the plurality of expanded base layers comprises a first resin containing a filler and a reinforced material, wherein the reinforced material is glass cloth, carbon cloth, non-woven glass fabric, or aramid cloth,
the filling insulating layer comprises a second resin containing a filler and not containing a reinforced material, and
the cover resin layer comprises a third resin not containing a filler and a reinforced material.

16. The semiconductor package of claim 11, wherein a surface of the semiconductor chip and the surface of the filling insulating layer are positioned at a same vertical level and are coplanar.

17. The semiconductor package of claim 11, wherein each of the plurality of first redistribution vias and each of the plurality of second redistribution vias have a tapered shape with a horizontal width decreasing closer to the semiconductor chip.

18. A semiconductor package comprising:
a first interconnection structure comprising a first redistribution insulating layer, a plurality of first redistribution line patterns arranged on at least one of a first surface and a second surface of the first redistribution insulating layer, and a plurality of first redistribution vias penetrating the first redistribution insulating layer and respectively connected to one or more of the plurality of first redistribution line patterns;
an expanded layer arranged on the first interconnection structure, the expanded layer comprising a plurality of expanded base layers, a cover resin layer covering a surface of at least one expanded base layer from an uppermost portion among the plurality of expanded base layers, a plurality of via structures penetrating the cover resin layer and the plurality of expanded base layers and respectively connected to one or more of the plurality of first redistribution vias, and a mounting space penetrating the plurality of expanded base layers, wherein the plurality of via structures comprise a plurality of via connection pattern portions and a plurality of extended via portions connecting two via connection pattern portions that are positioned at different vertical levels among the plurality of via connection pattern portions;
a semiconductor chip arranged in the mounting space and comprising a plurality of chip pads connected to a respective first redistribution via from the plurality of first redistribution vias and buried in the first redistribution insulating layer;
a filling insulating layer configured to fill the mounting space and cover a surface of the semiconductor chip and a surface of the expanded layer; and
a second interconnection structure arranged on the filling insulating layer, the second interconnection structure comprising a second redistribution insulating layer, a plurality of second redistribution line patterns arranged on at least one of a first surface and a second surface of the second redistribution insulating layer, and a plurality of second redistribution vias penetrating the second redistribution insulating layer and respectively connected to one or more of the plurality of second redistribution line patterns, the second interconnection structure being electrically connected to the first interconnection structure through the plurality of via structures,
wherein a surface of a lowermost expanded base layer among the plurality of expanded base layers is positioned at a higher vertical level than the surface of the filling insulating layer, and
wherein a portion of the first surface of the first redistribution insulating layer contacting the expanded layer is positioned at a higher vertical level than a portion of the first surface of the first redistribution insulating layer contacting the surface of the filling insulating layer.

19. The semiconductor package of claim 18, wherein the surface of the lowermost expanded base layer among the plurality of expanded base layers is positioned at a higher level than a surface of the semiconductor chip and the surface of the filling insulating layer by about 2 μm to about 5 μm.

20. The semiconductor package of claim 18, wherein a thickness of the cover resin layer is less than a thickness of each of the plurality of expanded base layers, and the thickness of each of the plurality of expanded base layers is in a range of about 20 μm to about 50 μm.
